(19) United States
(12) Patent Application Publication
(10) Pub. No.: US 2024/0113239 A1
(43) Pub. Date: Apr. 4, 2024

(54) INSULATION MODULE

(71) Applicant: ROHM CO., LTD., Kyoto-shi (JP)

(72) Inventors: Masahiko ARIMURA, Kyoto-shi (JP); Tomoichiro TOYAMA, Kyoto-shi (JP)

(21) Appl. No.: 18/537,297

(22) Filed: Dec. 12, 2023

Related U.S. Application Data
(63) Continuation of application No. PCT/JP2022/023702, filed on Jun. 14, 2022.

(30) Foreign Application Priority Data
Jun. 14, 2021 (JP) 2021-098854

(51) Int. Cl. H01L 31/0203; H01L 31/167

(52) U.S. Cl. CPC H01L 31/0203; H01L 31/167

(57) ABSTRACT

This insulation module includes: a first light-emitting element and a first light-receiving element that constitute a photocoupler; a first plate-shaped member that has light-transmitting properties and is provided between the first light-receiving element and the first light-emitting element; an encapsulation resin that at least encapsulates the light-emitting element and the light-receiving element; and a plurality of terminals that are provided to a first plastic side surface of the encapsulation resin. The first plate-shaped member is layered on the light-receiving surface of the first light-receiving element, and the first light-emitting element is layered on the first plate-shaped member. Recessed-projecting portions are provided to sections between adjacent terminals among the plurality of terminals on the first plastic side surface.

### BACKGROUND

The present disclosure relates to an insulation module.

As an insulation module, an insulation module of an optical system such as a photocoupler is known. For example, U.S. Pat. No. 9,000,675 discloses a configuration in which a light emitting surface of a light emitting element and a light receiving surface of a light receiving element face each other.

### BRIEF DESCRIPTION OF DRAWINGS

FIG. 1 is a perspective view of an insulation module according to an embodiment.

FIG. 2 is a plan view schematically illustrating an internal structure of the insulation module of FIG. 1.

FIG. 3 is a cross-sectional view of the insulation module of FIG. 2 taken along line 3-3.

FIG. 4 is an enlarged view of a light emitting element and its periphery in the insulation module of FIG. 3.

FIG. 5 is an enlarged view of a light emitting element, a light receiving element, and a periphery thereof in the insulation module of FIG. 3.

FIG. 6 is a cross-sectional view of the insulation module of FIG. 2 taken along line 6-6.

FIG. 7 is a cross-sectional view schematically illustrating an internal structure of a part of a light emitting element.

FIG. 8 is a cross-sectional view schematically illustrating an internal structure of a part of the light receiving element.

FIG. 9 is an enlarged plan view of a part of a sealing plastic of the insulation module of FIG. 1.

FIG. 10 is an enlarged plan view of a part of the sealing plastic of the insulation module of FIG. 1 different from that of FIG. 9.

FIG. 11 is a circuit diagram schematically illustrating an electrical configuration of the insulation module of FIG. 1.

FIG. 12 is an enlarged plan view illustrating a part of an internal structure of an insulation module according to a modification.

FIG. 13 is a cross-sectional view of a plate-shaped member and its periphery in an insulation module of a modification.

FIG. 14 is a cross-sectional view of a plate-shaped member and its periphery in an insulation module of a modification.

FIG. 15 is a cross-sectional view of a plate-shaped member and its periphery in an insulation module of a modification.

FIG. 16 is a cross-sectional view of a light receiving element and its periphery in an insulation module according to a modification.

FIG. 17 is a cross-sectional view schematically illustrating an internal structure of a part of the light receiving element of an insulation module according to a modification.

FIG. 18 is a cross-sectional view schematically illustrating an internal structure of a part of the light receiving element of an insulation module of a modification.

FIG. 19 is a circuit diagram schematically illustrating an electrical configuration of an insulation module according to a modification.

FIG. 20 is a circuit diagram schematically illustrating an electrical configuration of an insulation module according to a modification.

### DETAILED DESCRIPTION

Referring to the drawings, embodiments of an insulation module are now described. The embodiments described below illustrate configurations and methods for embodying technical ideas. The materials, shapes, structures, arrangements, dimensions, and the like of the components are not limited to those described below. For simplicity and clarity of illustration, components shown in the drawings are not necessarily drawn to scale. Also, to facilitate understanding, hatching lines may be omitted in cross-sectional views. The accompanying drawings are merely illustrative of embodiments of the disclosure and should not be considered as limiting the disclosure.

### Embodiments

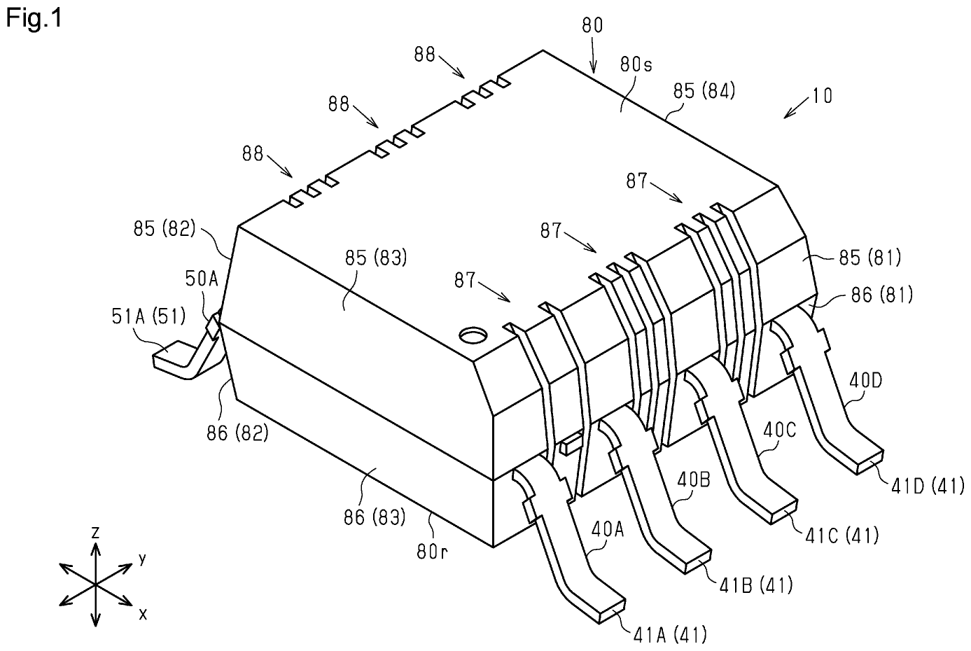

An insulation module 10 according to the present embodiment will be described with reference to FIGS. 1 to 11.

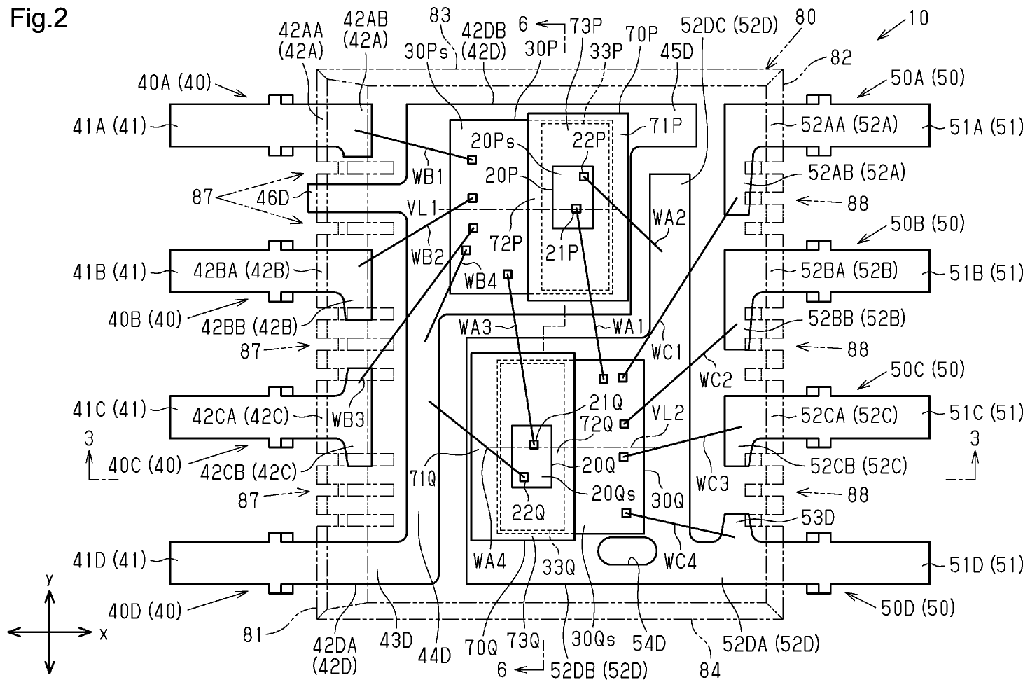

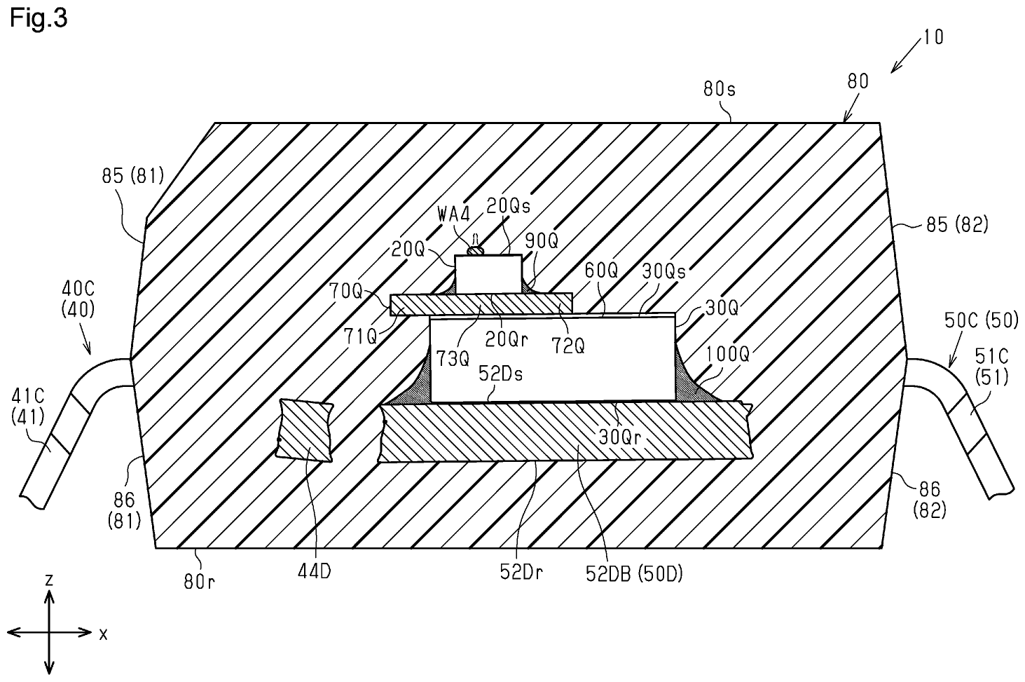

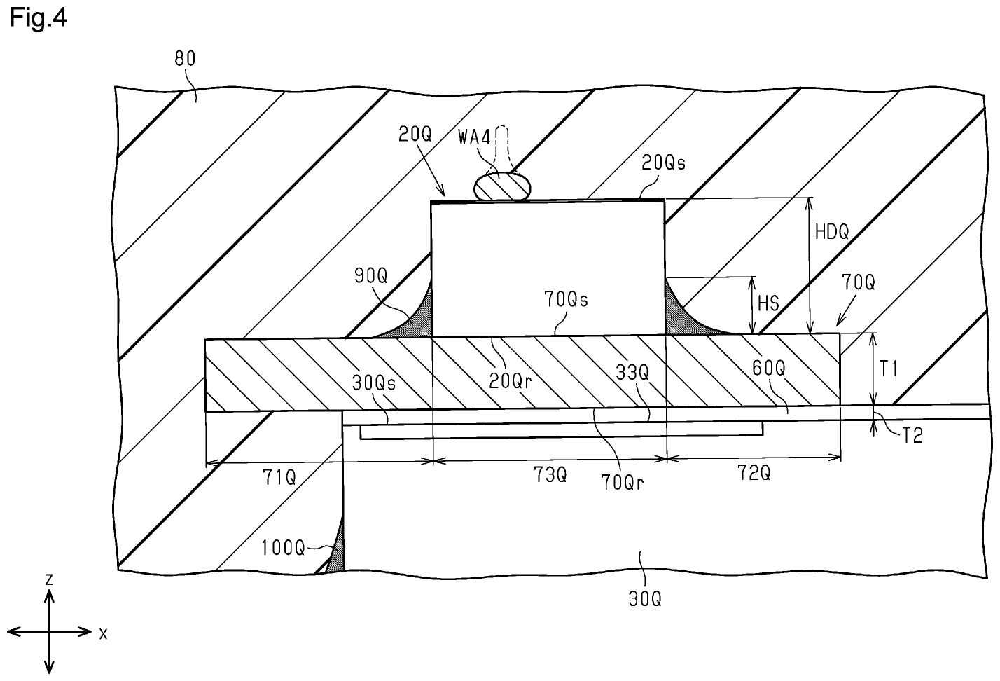

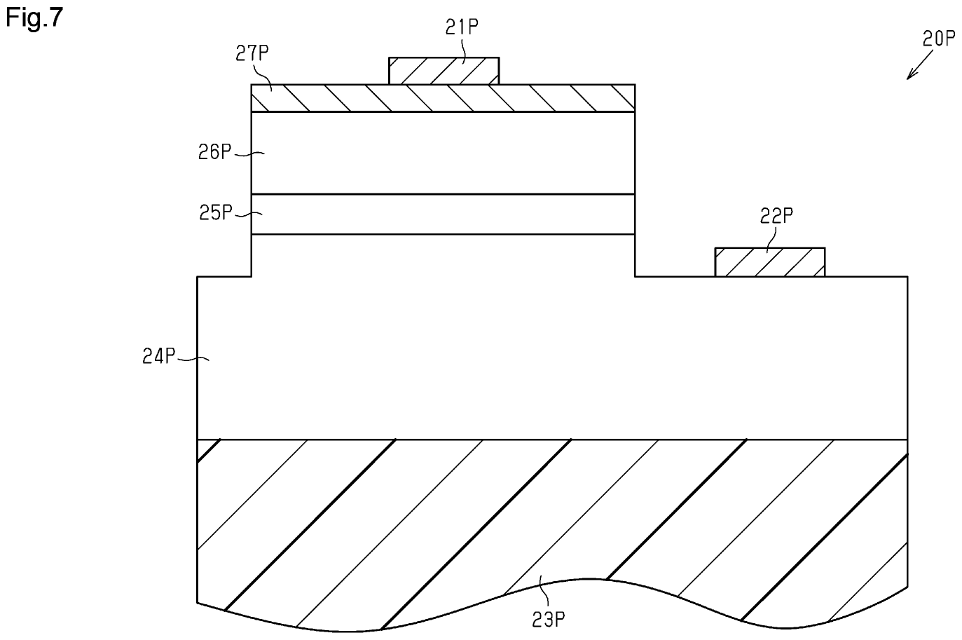

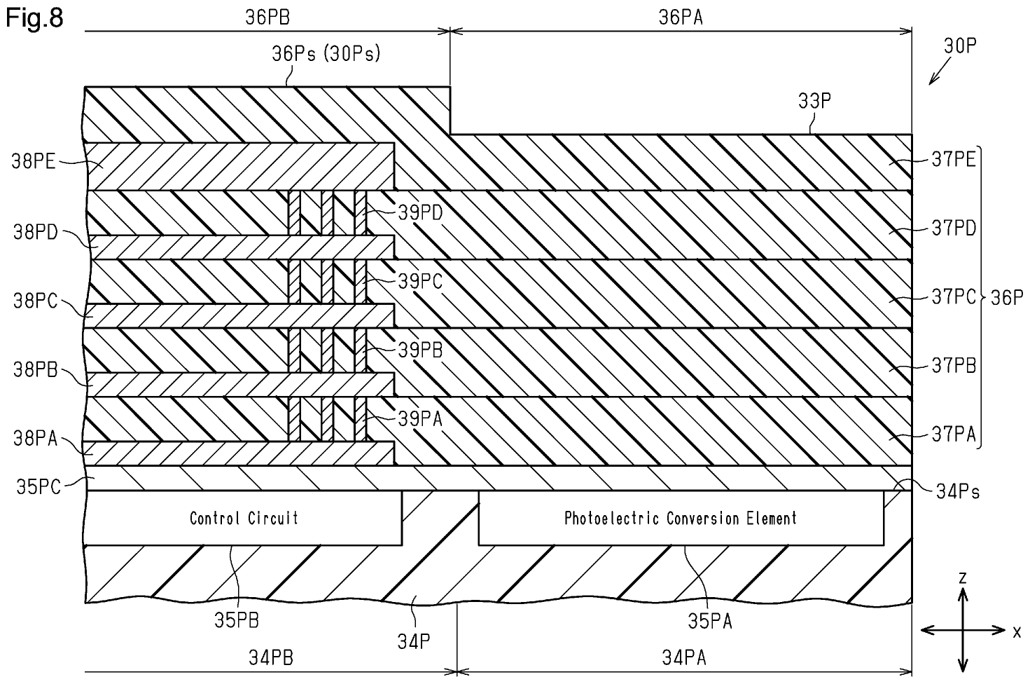

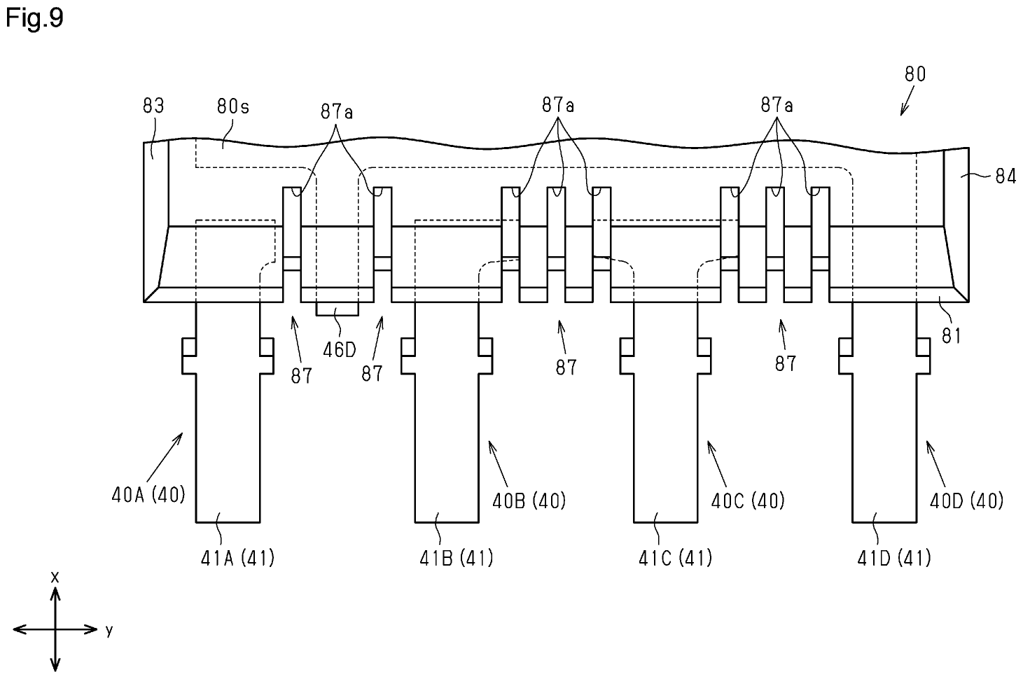

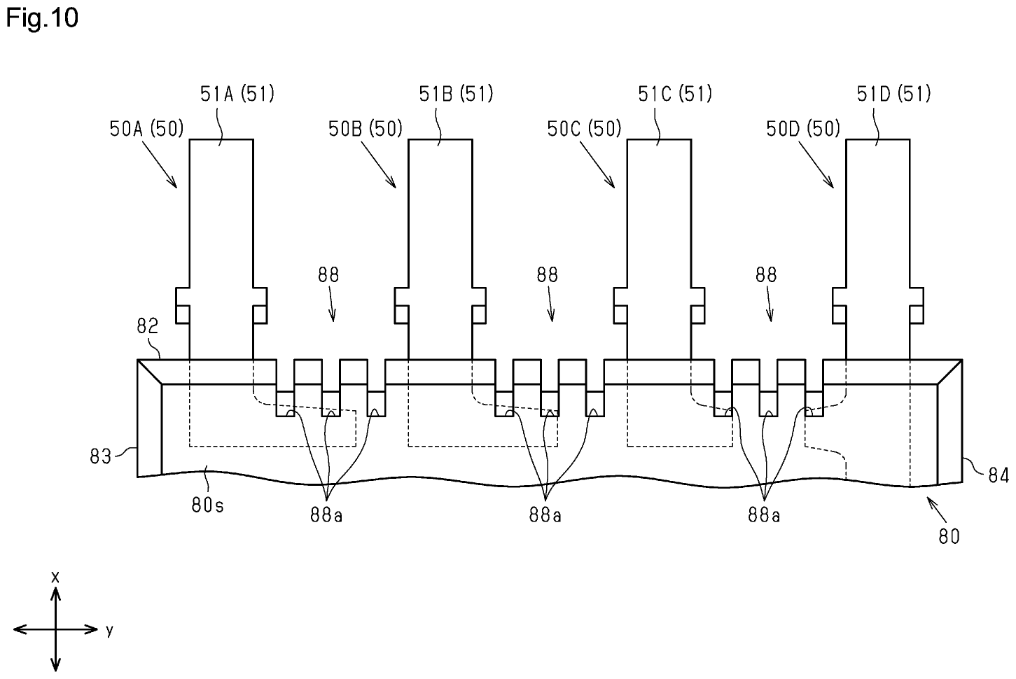

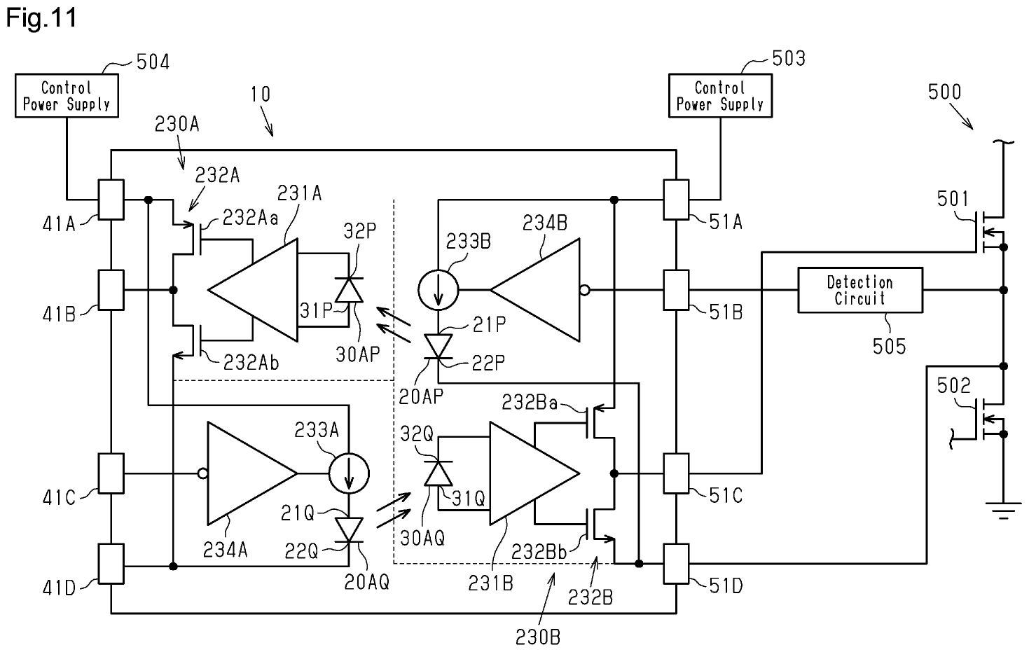

FIGS. 1 and 2 illustrate an overall structure of the insulation module 10. FIG. 3 illustrates an entire cross-sectional structure inside the insulation module 10, and FIGS. 4 to 6 illustrate a part of the cross-sectional structure inside the insulation module 10 in an enlarged manner. FIG. 7 illustrates an internal structure of a part of a first light emitting element 20P, and FIG. 8 illustrates an internal structure of a part of a first light receiving element 30P. FIGS. 9 and 10 illustrate an appearance of a part of the insulation module 10. FIG. 11 illustrates an example of a circuit configuration of the insulation module 10.

The insulation module 10 is used as a gate driver that applies a drive voltage signal to a gate of a switching element. As illustrated in FIGS. 1 and 2, a package structure of the insulation module 10 is a dual in-line package (DIP). The insulation module 10 includes a rectangular sealing plastic 80 and terminals 41 and 51 protruding from the sealing plastic 80. The withstand voltage of the insulation module 10 is, for example, in a range of 3500 Vrms to 7500 Vrms. However, the specific numerical value of the withstand voltage of the insulation module 10 is not limited to this, and the value is arbitrarily set.

The sealing plastic 80 is formed of an insulation material having a light shielding property. An example of the insulation material is an epoxy resin. In the present embodiment, the sealing plastic 80 is formed of a black epoxy resin. As illustrated in FIGS. 1 and 2, the sealing plastic 80 has a plastic main surface 80s, a plastic back surface 80r, and first to fourth plastic side surfaces 81 to 84. In the following description, a thickness direction of the sealing plastic 80 is defined as a z-direction, and two directions orthogonal to each other among directions orthogonal to the z-direction are defined as an x-direction and a y-direction, respectively. It can also be said that the z-direction is the “height direction of the insulation module”.

The plastic main surface 80s and the plastic back surface 80r form opposite end faces in the thickness direction (z-direction) of the sealing plastic 80. When viewed from the z-direction, both the plastic main surface 80s and the plastic back surface 80r are formed to have a rectangular shape. In the present embodiment, the shape of both the plastic main surface 80s and the plastic back surface 80r viewed from the z-direction is a rectangular shape in which the x-direction is a short side and the y-direction is a long side.

The first plastic side surface 81 and the second plastic side surface 82 form opposite end faces in the x-direction. Both the first plastic side surface 81 and the second plastic side surface 82 extend along the y-direction as viewed from the z-direction. Multiple (four in the present embodiment) terminals 41A to 41D are provided on the first plastic side surface 81, and multiple (four in the present embodiment) terminals 51A to 51D are provided on the second plastic side surface 82. In the present embodiment, both the first plastic side surface 81 provided with the terminals 41A to 41D and the second plastic side surface 82 provided with the terminals 51A to 51D correspond to “terminal surfaces”.

The terminals 41A to 41D protrude from the first plastic side surface 81. The terminals 51A to 51D protrude from the second plastic side surface 82. Therefore, the terminals 41A to 41D and the terminals 51A to 51D are arranged side by side at intervals in the x-direction when viewed from the z-direction. That is, the x-direction is an arrangement direction of the terminals 41A to 41D and the terminals 51A to 51D. As illustrated in FIGS. 1 and 2, the terminals 51A to 51D have the same shape as the terminals 41A to 41D. In this manner, the terminals 41A to 41D are provided side by side on the first plastic side surface 81, and the terminals 51A to 51D are provided side by side on the second plastic side surface 82.

The third plastic side surface 83 and the fourth plastic side surface 84 form opposite end faces in the y-direction. Both the third plastic side surface 83 and the fourth plastic side surface 84 are side surfaces on which the terminals 41A to 41D and 51A to 51D are not provided. Both the third plastic side surface 83 and the fourth plastic side surface 84 extend along the x-direction as viewed from the z-direction.

In the present embodiment, the terminals 41A to 41D and 51A to 51D have the same shape. More specifically, as shown in FIG. 1, each of the terminals 41A to 41D has a first portion extending in the x-direction from the first plastic side surface 81, a first bent portion bent downward from the first portion, a second portion extending so as to be inclined downward as separating from the sealing plastic 80 in the x-direction, a second bent portion bent outward from the second portion, and a third portion extending so as to be inclined downward as separating from the sealing plastic 80 in the x-direction. An inclination angle of the third portion with respect to the z-direction is smaller than an inclination angle of the second portion with respect to the z-direction. In the present embodiment, each of the terminals 41A to 41D and 51A to 51D has a so-called gull-wing-type terminal.

When the insulation module 10 is mounted on, for example, a wiring board (not illustrated), the terminals 41A to 41D and 51A to 51D form external terminals mounted on lands provided on the wiring board. Each of the terminals 41A to 41D and 51A to 51D is bonded to a land of the wiring board with a conductive bonding material formed of, for example, solder, silver (Ag) paste, or the like. Thus, the insulation module 10 is electrically connected to the wiring board.

Each plastic side surface 81 to 84 has a first side surface 85 and a second side surface 86. The first side surface 85 is continuous with the second side surface 86. The first side surface 85 is disposed closer to the plastic main surface 80s than the plastic back surface 80r in the z-direction. The second side surface 86 is disposed closer to the plastic back surface 80r than the plastic main surface 80s in the z-direction. The first side surface 85 of the first plastic side surface 81 and the first side surface 85 of the second plastic side surface 82 are inclined so as to approach each other in the x-direction toward the plastic main surface 80s, and the second side surface 86 of the first plastic side surface 81 and the second side surface 86 of the second plastic side surface 82 are inclined so as to approach each other in the x-direction toward the plastic back surface 80r. The first side surface 85 (not shown) of the third plastic side surface 83 and the first side surface 85 of the fourth plastic side surface 84 are inclined so as to approach each other in the y-direction toward the plastic main surface 80s, and the second side surface 86 (not shown) of the third plastic side surface 83 and the second side surface 86 of the fourth plastic side surface 84 are inclined so as to approach each other in the y-direction toward the plastic back surface 80r.

Each of the four terminals 41A to 41D protrudes from a portion between the first side surface 85 and the second side surface 86 of the first plastic side surface 81. The four terminals 41A to 41D are arranged apart from each other in the y-direction.

Each of the four terminals 51A to 51D protrudes from a portion between the first side surface 85 and the second side surface 86 of the second plastic side surface 82. The four terminals 51A to 51D are arranged apart from each other in the y-direction.

Next, a structure in the sealing plastic 80 will be described.

FIG. 2 is a plan view of the insulation module 10 illustrating an internal structure of the insulation module 10. In FIG. 2, the sealing plastic 80 is indicated by a long-dash double-short-dash line for illustrative purposes.

As illustrated in FIG. 2, the insulation module 10 includes a first light emitting element 20P and a second light emitting element 20Q, a first light receiving element 30P and a second light receiving element 30Q, a first lead frame 40, and a second lead frame 50. The first light emitting element 20P and the first light receiving element 30P form a first photocoupler, and the second light emitting element 20Q and the second light receiving element 30Q form a second photocoupler. The sealing plastic 80 seals at least each of the light emitting elements 20P and 20Q and each of the light receiving elements 30P and 30Q.

In the present embodiment, the first lead frame 40 is a lead frame electrically connected to the first light receiving element 30P, and the second lead frame 50 is a lead frame electrically connected to the second light receiving element 30Q.

The first lead frame 40 includes first lead frames 40A to 40D as four first lead frames. The first lead frames 40A to 40D are arranged apart from each other in the y-direction when viewed from the z-direction.

The first lead frame 40A is disposed closer to the third plastic side surface 83 than the first lead frames 40B to 40D. The first lead frame 40A includes a terminal 41A. That is, the terminal 41A is a portion of the first lead frame 40A protruding from the first plastic side surface 81 to the outside of the sealing plastic 80.

An inner lead 42A, which is a portion of the first lead frame 40A provided in the sealing plastic 80, has a lead portion 42AA and a wire connection portion 42AB.

The lead portion 42AA is a portion continuous with the terminal 41A and extends in the x-direction. The wire connection portion 42AB is provided at a distal end portion of the lead portion 42AA. The wire connection portion 42AB has a portion extending in the y-direction toward the fourth plastic side surface 84 with respect to the lead portion 42AA. That is, the wire connection portion 42AB has a portion protruding toward the fourth plastic side surface 84 with respect to the lead portion 42AA. The sealing plastic 80 exists on the opposite sides of the wire connection portion 42AB in the x-direction. Therefore, the wire connection portion 42AB prevents the first lead frame 40A from moving in the x-direction with respect to the sealing plastic 80.

The first lead frame 40B is disposed close to the fourth plastic side surface 84 with respect to the first lead frame 40A. The first lead frame 40B includes a terminal 41B. That is, the terminal 41B is a portion of the first lead frame 40B protruding from the first plastic side surface 81 to the outside of the sealing plastic 80.

An inner lead 42B, which is a portion of the first lead frame 40B provided in the sealing plastic 80, has a lead portion 42BA and a wire connection portion 42BB.

The lead portion 42BA is a portion continuous with the terminal 41B and extends in the x-direction. The wire connection portion 42BB is provided at a distal end portion of the lead portion 42BA. The wire connection portion 42BB has a portion extending in the y-direction toward the fourth plastic side surface 84 with respect to the lead portion 42BA. That is, the wire connection portion 42BB has a portion protruding toward the fourth plastic side surface 84 with respect to the lead portion 42BA. In the present embodiment, the length of the wire connection portion 42BB in the y-direction is longer than the length of the wire connection portion 42AB in the y-direction. The sealing plastic 80 exists on the opposite sides of the wire connection portion 42BB in the x-direction. Therefore, the wire connection portion 42BB prevents the first lead frame 40B from moving in the x-direction with respect to the sealing plastic 80.

The first lead frame 40C is disposed closer to the fourth plastic side surface 84 than the first lead frame 40B. The first lead frame 40C includes a terminal 41C. That is, the terminal 41C is a portion of the first lead frame 40C protruding from the first plastic side surface 81 to the outside of the sealing plastic 80.

An inner lead 42C, which is a portion of the first lead frame 40C provided in the sealing plastic 80, has a lead portion 42CA and a wire connection portion 42CB.

The lead portion 42CA is a portion continuous with the terminal 41C and extends in the x-direction. The wire connection portion 42CB is provided at a distal end portion of the lead portion 42CA. The wire connection portion 42CB has portions extending to the opposite sides in the y-direction with respect to the lead portion 42CA. That is, the wire connection portion 42CB has portions protruding toward the opposite sides in the y-direction with respect to the lead portion 42CA. In the present embodiment, the length of the wire connection portion 42CB in the y-direction is longer than the length of the wire connection portion 42BB in the y-direction. The sealing plastic 80 exists on the opposite sides of the wire connection portion 42CB in the x-direction. Therefore, the wire connection portion 42CB prevents the first lead frame 40C from moving in the x-direction with respect to the sealing plastic 80.

The first lead frame 40D is disposed closer to the fourth plastic side surface 84 than the first lead frame 40C. The first lead frame 40D includes a terminal 41D. That is, the terminal 41D is a portion of the first lead frame 40D protruding from the first plastic side surface 81 to the outside of the sealing plastic 80.

An inner lead 42D, which is a portion of the first lead frame 40D provided in the sealing plastic 80, has a lead portion 42DA and a die pad portion 42DB. In the present embodiment, the die pad portion 42DB corresponds to a “die pad”.

The lead portion 42DA is a portion continuous with the terminal 41D, and has a first portion 43D extending in the x-direction and a second portion 44D extending in the y-direction. The first portion 43D is continuous with the terminal 41D. The second portion 44D is a portion connecting the first portion 43D and the die pad portion 42DB. The second portion 44D is disposed closer to the second plastic side surface 82 than the first lead frames 40A to 40C. When viewed from the x-direction, the second portion 44D extends to a position overlapping the first lead frame 40C. The width of the second portion 44D (the length of the second portion 44D being in the y-direction) is narrower than the width of the first portion 43D (the length of the first portion 43D being in the x-direction).

The die pad portion 42DB is disposed closer to the third plastic side surface 83 than the center of the sealing plastic 80 in the y-direction. The die pad portion 42DB is disposed closer to the second plastic side surface 82 than the first lead frames 40A to 40C in the x-direction. The shape of the die pad portion 42DB viewed from the z-direction is a rectangular shape in which the x-direction is a long side and the y-direction is a short side. When viewed from the x-direction, the die pad portion 42DB is provided so as to overlap the first lead frames 40A and 40B. The die pad portion 42DB is provided with a protrusion 45D and a suspension lead 46D.

The protrusion 45D extends in the x-direction toward the second plastic side surface 82 from a corner closer to the second plastic side surface 82 and closer to the third plastic side surface 83 among the four corners of the die pad portion 42DB. The width of the protrusion 45D (the length of the protrusion 45D in the y-direction) is equal to the width of the lead portion 42AA (the length of the lead portion 42AA in the y-direction). That is, the width of the protrusion 45D is greater than the width of the second portion 44D.

The suspension lead 46D extends in the x-direction toward the first plastic side surface 81 from the end closer to the first plastic side surface 81 of the opposite ends in the x-direction of the die pad portion 42DB. The distal end of the suspension lead 46D is exposed from the first plastic side surface 81. The suspension lead 46D is disposed between the first lead frame 40A and the first lead frame 40B in the y-direction. That is, a portion of the suspension lead 46D exposed from the first plastic side surface 81 is located between the terminal 41A and terminal 41B in the y-direction.

The second lead frame 50 includes second lead frames 50A to 50D as four second lead frames. The second lead frames 50A to 50D are arranged apart from each other in the y-direction when viewed from the z-direction.

The second lead frame 50A is disposed closer to the third plastic side surface 83 than the second lead frames 50B to 50D. The second lead frame 50A includes a terminal 51A. That is, the terminal 51A is a portion of the second lead frame 50A protruding from the second plastic side surface 82 to the outside of the sealing plastic 80. In the present embodiment, the terminal 51A is disposed at a position overlapping the terminal 41A when viewed from the x-direction.

An inner lead 52A, which is a portion of the second lead frame 50A provided in the sealing plastic 80, has a lead portion 52AA and a wire connection portion 52AB.

The lead portion 52AA is a portion continuous with the terminal 51A and extends in the x-direction. The wire connection portion 52AB is provided at a distal end portion of the lead portion 52AA. The wire connection portion 52AB has a portion extending in the y-direction toward the fourth plastic side surface 84 with respect to the lead portion 52AA. That is, the wire connection portion 52AB has a portion protruding toward the fourth plastic side surface 84 with respect to the lead portion 52AA. The length of the wire connection portion 52AB in the y-direction is longer than the length of the wire connection portion 42AB of the first lead frame 40A in the y-direction. The length of the wire connection portion 52AB in the y-direction is longer than the length of the wire connection portion 42CB of the first lead frame 40C in the y-direction. The lead portion 52AA and the wire connection portion 52AB are disposed at positions facing the protrusion 45D of the first lead frame 40D in the x-direction. The wire connection portion 52AB is disposed closer to the second plastic side surface 82 than the protrusion 45D. The sealing plastic 80 exists on the opposite sides of the wire connection portion 52AB in the x-direction. Therefore, the wire connection portion 52AB prevents the second lead frame 50A from moving in the x-direction with respect to the sealing plastic 80.

The second lead frame 50B is disposed closer to the fourth plastic side surface 84 than the second lead frame 50A. The second lead frame 50B includes a terminal 51B. That is, the terminal 51B is a portion of the second lead frame 50B protruding from the second plastic side surface 82 to the outside of the sealing plastic 80. In the present embodiment, the terminal 51B is disposed at a position overlapping the terminal 41B when viewed from the x-direction.

An inner lead 52B, which is a portion of the second lead frame 50B provided in the sealing plastic 80, has a lead portion 52BA and a wire connection portion 52BB.

The lead portion 52BA is a portion continuous with the terminal 51B and extends in the x-direction. The wire connection portion 52BB is provided at a distal end portion of the lead portion 52BA. The wire connection portion 52BB has a portion extending in the y-direction toward the fourth plastic side surface 84 with respect to the lead portion 52BA. That is, the wire connection portion 52BB has a portion protruding toward the fourth plastic side surface 84 with respect to the lead portion 52BA. The length of the wire connection portion 52BB in the y-direction is shorter than the length of the wire connection portion 52AB of the second lead frame 50A in the y-direction. The lead portion 52BA and the wire connection portion 52BB are disposed at positions facing the die pad portion 42DB of the first lead frame 40D in the x-direction. The wire connection portion 52BB is disposed closer to the second plastic side surface 82 than the protrusion 45D. The sealing plastic 80 exists on the opposite sides of the wire connection portion 52BB in the x-direction. Therefore, the wire connection portion 52BB prevents the second lead frame 50B from moving in the x-direction with respect to the sealing plastic 80.

The second lead frame 50C is disposed closer to the fourth plastic side surface 84 than the second lead frame 50B. The second lead frame 50C includes a terminal 51C. That is, the terminal 51C is a portion of the second lead frame 50C protruding from the second plastic side surface 82 to the outside of the sealing plastic 80. In the present embodiment, the terminal 51C is disposed at a position overlapping the terminal 41C when viewed from the x-direction.

An inner lead 52C, which is a portion of the second lead frame 50C provided in the sealing plastic 80, has a lead portion 52CA and a wire connection portion 52CB.

The lead portion 52CA is a portion continuous with the terminal 51C and extends in the x-direction. The wire connection portion 52CB is provided at a distal end portion of the lead portion 52CA. The wire connection portion 52CB has a portion extending in the y-direction toward the fourth plastic side surface 84 with respect to the lead portion 52CA. That is, the wire connection portion 52CB has a portion protruding toward the fourth plastic side surface 84 with respect to the lead portion 52CA. The length of the wire connection portion 52CB in the y-direction is shorter than the length of the wire connection portion 52BB of the second lead frame 50B in the y-direction. The lead portion 52CA and the wire connection portion 52CB are disposed closer to the fourth plastic side surface than the die pad portion 42DB of the first lead frame 40D in the x-direction. The wire connection portion 52CB is disposed closer to the second plastic side surface 82 than the die pad portion 42DB. The sealing plastic 80 exists on the opposite sides of the wire connection portion 52CB in the x-direction. Therefore, the wire connection portion 52CB prevents the second lead frame 50C from moving in the x-direction with respect to the sealing plastic 80.

The second lead frame 50D is disposed closer to the fourth plastic side surface 84 than the second lead frame 50C. The second lead frame 50D includes a terminal 51D. That is, the terminal 51D is a portion of the second lead frame 50D protruding from the second plastic side surface 82 to the outside of the sealing plastic 80. In the present embodiment, the terminal 51D is disposed at a position overlapping the terminal 41D when viewed from the x-direction.

An inner lead 52D, which is a portion of the second lead frame 50D provided in the sealing plastic 80, includes a lead portion 52DA, a die pad portion 52DB, and a wire connection portion 52DC.

The lead portion 52DA is a portion continuous with the terminal 51D and extends in the x-direction. The length of the lead portion 52DA in the x-direction is longer than the lengths of the lead portions 52AA to 52CA in the x-direction. The lead portion 52DA is connected to the die pad portion 52DB.

The die pad portion 52DB is disposed closer to the fourth plastic side surface 84 than the center of the sealing plastic 80 in the y-direction. The die pad portion 52DB is disposed closer to the fourth plastic side surface 84 than the die pad portion 42DB of the first lead frame 40D. The die pad portion 52DB is arranged side by side with the die pad portion 42DB in the y-direction. The die pad portion 52DB is disposed closer to the first plastic side surface 81 than the second lead frames 50A to 50C in the x-direction. The shape of the die pad portion 52DB viewed from the z-direction is a rectangular shape in which the x-direction is a short side and the y-direction is a long side. When viewed from the x-direction, the die pad portion 52DB is provided so as to overlap the second lead frame 50C. The wire connection portion 52DC is provided at a corner close to the third plastic side surface 83 and close to the second plastic side surface 82 among the four corners of the die pad portion 52DB.

The wire connection portion 52DC extends in the y-direction from the die pad portion 52DB toward the third plastic side surface 83. The wire connection portion 52DC is disposed closer to the second plastic side surface 82 than the die pad portion 42DB of the first lead frame 40D, and is disposed at a position overlapping the die pad portion 42DB when viewed from the x-direction. The wire connection portion 52DC is disposed closer to the first plastic side surface 81 than the second lead frames 50A and 50B, and is disposed at a position overlapping the second lead frames 50A and 50B when viewed from the x-direction. That is, the wire connection portion 52DC is disposed between the die pad portion 42DB and the second lead frames 50A and 50B in the x-direction.

A wire connection portion 53D is provided in a portion of the lead portion 52DA close to the die pad portion 52DB. The wire connection portion 53D is a portion extending in the y-direction from the lead portion 52DA toward the third plastic side surface 83. The wire connection portion 53D is disposed at a position aligned with the wire connection portion 52CB of the second lead frame 50C in the x-direction.

A through hole 54D is provided in a portion of the die pad portion 52DB close to the fourth plastic side surface 84. The through hole 54D is provided at a position overlapping with the lead portion 52DA when viewed from the x-direction. The through hole 54D is filled with a sealing plastic 80. The sealing plastic 80 in the through hole 54D prevents the second lead frame 50D from moving in the direction orthogonal to the z-direction with respect to the sealing plastic 80.

As illustrated in FIG. 2, the first light receiving element 30P is mounted on the die pad portion 42DB of the first lead frame 40D, and the second light receiving element 30Q is mounted on the die pad portion 52DB of the second lead frame 50D. The first light emitting element 20P is mounted on the first light receiving element 30P, and the second light emitting element 20Q is mounted on the second light receiving element 30Q. In the present embodiment, the first light receiving element 30P and the second light receiving element 30Q are light receiving elements having the same shape and size. The first light emitting element 20P and the second light emitting element 20Q are light emitting elements having the same shape and size. In the present embodiment, the die pad portion 42DB corresponds to a “first die pad”, and the die pad portion 52DB corresponds to a “second die pad”.

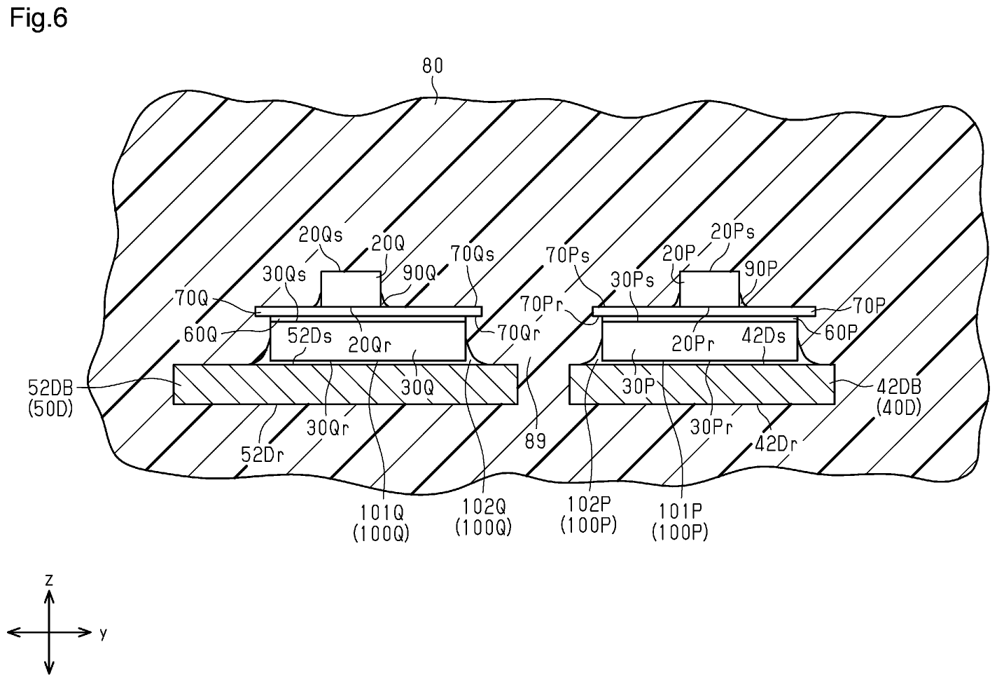

The first light receiving element 30P is disposed closer to the second plastic side surface 82 than the die pad portion 42DB. That is, the center of the first light receiving element 30P in the x-direction is located closer to the second plastic side surface 82 than the center of the die pad portion 42DB in the x-direction. In the present embodiment, the first light receiving element 30P is disposed closer to the second plastic side surface 82 than the lead portion 42DA in the x-direction. The first light receiving element 30P is bonded to the die pad portion 42DB by a conductive bonding material 100P (see FIG. 6) such as solder or silver (Ag) paste. The first light receiving element 30P is bonded to the die pad portion 42DB by being die-bonded to the die pad portion 42DB. The shape of the first light receiving element 30P viewed from the z-direction is a rectangular shape in which the x-direction is a short side and the y-direction is a long side. In the present embodiment, the conductive bonding material 100P corresponds to a “bonding material for light reception”.

The second light receiving element 30Q is disposed closer to the first plastic side surface 81 than the die pad portion 52DB. That is, the center of the second light receiving element 30Q in the x-direction is located closer to the first plastic side surface 81 than the center of the die pad portion 52DB in the x-direction. In the present embodiment, the second light receiving element 30Q is disposed closer to the first plastic side surface 81 than the wire connection portion 52DC in the x-direction. The second light receiving element 30Q is bonded to the die pad portion 52DB by a conductive bonding material 100Q (see FIG. 6) such as solder or Ag paste. The second light receiving element 30Q is bonded to the die pad portion 52DB by being die-bonded to the die pad portion 52DB. In the present embodiment, the conductive bonding material 100Q corresponds to a “bonding material for light reception”.

The first light receiving element 30P and the second light receiving element 30Q are arranged side by side in the y-direction. More specifically, the first light receiving element 30P and the second light receiving element 30Q are disposed at positions overlapping each other when viewed from the y-direction. On the other hand, the first light receiving element 30P and the second light receiving element 30Q are arranged to be shifted from each other in the x-direction. The first light receiving element 30P is arranged to be shifted toward the first plastic side surface 81 with respect to the second light receiving element 30Q in the x-direction. That is, the end closer to the first plastic side surface 81 of the opposite ends in the x-direction of the first light receiving element 30P is disposed closer to the first plastic side surface 81 than the second light receiving element 30Q as viewed from the y-direction. The second light receiving element 30Q is arranged to be shifted toward the second plastic side surface 82 with respect to the first light receiving element 30P in the x-direction. That is, the end closer to the second plastic side surface 82 of the opposite ends in the x-direction of the second light receiving element 30Q is disposed closer to the second plastic side surface 82 than the first light receiving element 30P is when viewed from the y-direction.

The first light emitting element 20P is disposed at a position overlapping the first light receiving element 30P when viewed from the z-direction. More specifically, the first light emitting element 20P is disposed closer to the second plastic side surface 82 than the center of the first light receiving element 30P in the x-direction when viewed from the z-direction. The end edge closer to the second plastic side surface 82 of the opposite end edges in the x-direction of the first light emitting element 20P is disposed closer to the first plastic side surface 81 than the end edge closer to the second plastic side surface 82 of the opposite end edges in the x-direction of the first light receiving element 30P. The end edge closer to the first plastic side surface 81 of the opposite end edges of the first light emitting element 20P in the x-direction is disposed closer to the second plastic side surface 82 than the center of the first light receiving element 30P in the x-direction. The first light emitting element 20P is disposed closer to the third plastic side surface 83 than the center of the first light receiving element 30P in the y-direction as viewed from the z-direction. More specifically, the first light emitting element 20P is disposed at a position overlapping a first virtual line VL1 extending along the x-direction at the center of the first light receiving element 30P in the y-direction when viewed from the z-direction. The center of the first light emitting element 20P in the y-direction is disposed closer to the third plastic side surface 83 than the first virtual line VL1.

The shape of the first light emitting element 20P viewed from the z-direction is a rectangular shape in which the x-direction is a short side and the y-direction is a long side. When viewed from the z-direction, the area of the first light emitting element 20P is smaller than ½ of the area of the first light receiving element 30P. When viewed from the z-direction, the area of the first light emitting element 20P is greater than 1/10 of the area of the first light receiving element 30P and smaller than ½ of the area of the first light receiving element 30P. In one example, the area of the first light emitting element 20P is about 1/9 of the area of the first light receiving element 30P when viewed from the z-direction.

As illustrated in FIG. 6, the first light emitting element 20P has an element main surface 20Ps and an element back surface 20Pr facing opposite sides in the thickness direction of the first light emitting element 20P. The element main surface 20Ps faces the same side as a pad main surface 42Ds of the die pad portion 42DB, and the element back surface 20Pr faces the same side as a pad back surface 42Dr. In the present embodiment, the element back surface 20Pr forms a light emitting surface of the first light emitting element 20P. Therefore, the element main surface 20Ps corresponds to the “back surface facing the side opposite to the light emitting surface”.

As illustrated in FIG. 2, the second light emitting element 20Q is disposed at a position overlapping the second light receiving element 30Q when viewed from the z-direction. More specifically, the second light emitting element 20Q is disposed closer to the first plastic side surface 81 than the center of the second light receiving element 30Q in the x-direction when viewed from the z-direction. The end edge closer to the first plastic side surface 81 of the opposite end edges in the x-direction of the second light emitting element 20Q is disposed closer to the second plastic side surface 82 than the end edge closer to the first plastic side surface 81 of the opposite end edges in the x-direction of the second light receiving element 30Q. The end edge closer to the second plastic side surface 82 of the opposite end edges of the second light emitting element 20Q in the x-direction is disposed closer to the first plastic side surface 81 than the center of the second light receiving element 30Q in the x-direction. The second light emitting element 20Q is disposed closer to the fourth plastic side surface 84 than the center of the second light receiving element 30Q in the y-direction as viewed from the z-direction. More specifically, the second light emitting element 20Q is disposed at a position overlapping a second virtual line VL2 extending along the x-direction at the center of the second light receiving element 30Q in the y-direction when viewed from the z-direction. The center of the second light emitting element 20Q in the y-direction is disposed closer to the fourth plastic side surface 84 than the second virtual line VL2. Since the relationship between the area of the second light emitting element 20Q and the area of the second light receiving element 30Q viewed from the z-direction is the same as that of the first light emitting element 20P and the first light receiving element 30P, detailed description thereof will be omitted.

As illustrated in FIG. 6, the first light emitting element 20P has an element main surface 20Qs and an element back surface 20Qr facing opposite sides in the thickness direction of the second light emitting element 20Q. The element main surface 20Qs faces the same side as a pad main surface 52Ds of the die pad portion 52DB, and the element back surface 20Qr faces the same side as a pad back surface 52Dr. In the present embodiment, the element back surface 20Qr forms a light emitting surface of the second light emitting element 20Q. Therefore, the element main surface 20Qs corresponds to the “back surface facing the side opposite to the light emitting surface”.

As illustrated in FIG. 2, the first light emitting element 20P and the second light emitting element 20Q are disposed apart from each other in the y-direction. The first light emitting element 20P is disposed closer to the second plastic side surface 82 than the second light emitting element 20Q. In other words, the second light emitting element 20Q is disposed closer to the first plastic side surface 81 than the first light emitting element 20P. When viewed from the y-direction, the first light emitting element 20P and the second light emitting element 20Q are disposed at positions not overlapping each other.

The first light emitting element 20P emits light having a first wavelength. An example of the light having the first wavelength is light having a wavelength including infrared rays. The second light emitting element 20Q emits light having a second wavelength different from the first wavelength. An example of the light having the second wavelength is light having a wavelength including red. Both the first light emitting element 20P and the second light emitting element 20Q emit light downward.

The first light receiving element 30P is formed to receive light (light having the first wavelength) from the first light emitting element 20P. The first light receiving element 30P includes a first semiconductor region that receives light from the first light emitting element 20P and a second semiconductor region that generates a signal based on the received light. The first semiconductor region includes a photoelectric conversion element. For example, a photodiode is used as the photoelectric conversion element. The second semiconductor region is formed by, for example, large scale integration (LSI). That is, the first light receiving element 30P of the present embodiment is an element in which a function of receiving light from the first light emitting element 20P and a function of generating a signal from the received light are integrated. When viewed from the z-direction, the first semiconductor region and the second semiconductor region are formed side by side in the x-direction. When viewed from the z-direction, the first semiconductor region is formed in a portion of the first light receiving element 30P overlapping the first light emitting element 20P when viewed from the z-direction. In other words, the first light emitting element 20P is arranged closer to the photoelectric conversion element with respect to the first light receiving element 30P. The second semiconductor region is formed in a portion of the first light receiving element 30P closer to the second plastic side surface 82 when viewed from the z-direction. The area of the first semiconductor region viewed from the z-direction is smaller than the area of the second semiconductor region viewed from the z-direction. When viewed from the z-direction, the dimension of the first semiconductor region in the x-direction is smaller than the dimension of the second semiconductor region in the x-direction. When viewed from the z-direction, the first semiconductor region of the first light receiving element 30P forms a light receiving surface 33P. That is, the first light emitting element 20P is disposed at a position overlapping a light receiving surface 33P of the first light receiving element 30P when viewed from the z-direction. Therefore, the light receiving surface 33P of the first light receiving element 30P faces the element back surface 20Pr (light emitting surface) of the first light emitting element 20P.

The second light receiving element 30Q is formed to receive light (light having the second wavelength) from the second light emitting element 20Q. Since the second light receiving element 30Q has the same configuration as the first light receiving element 30P, the detailed description thereof will be omitted. Similarly, the second light receiving element 30Q also has a light receiving surface 33Q as the first semiconductor region. When viewed from the z-direction, the second light emitting element 20Q is disposed at a position overlapping the light receiving surface 33Q of the second light receiving element 30Q. Therefore, the light receiving surface 33Q of the second light receiving element 30Q faces the element back surface 20Qr (light emitting surface) of the second light emitting element 20Q. The second light emitting element 20Q is disposed closer to the photoelectric conversion element than the second light receiving element 30Q.

As illustrated in FIG. 6, the first light receiving element 30P has an element main surface 30Ps and an element back surface 30Pr facing opposite sides in the thickness direction of the first light receiving element 30P. The element main surface 30Ps faces the same side as a pad main surface 42Ds of the die pad portion 42DB, and the element back surface 30Pr faces the same side as a pad back surface 42Dr. The element main surface 30Ps includes the light receiving surface 33P. Therefore, in the present embodiment, the element back surface 30Pr forms a “back surface facing opposite side the light receiving surface”. Further, the element main surface 30Ps faces the same side as the plastic main surface 80s (see FIG. 3) of the sealing plastic 80, and the element back surface 30Pr faces the same side as the plastic back surface 80r (see FIG. 3) of the sealing plastic 80. That is, the light receiving surface 33P faces the same side as the plastic main surface 80s, and the element back surface 20Pr of the first light emitting element 20P, which is a light emitting surface facing the light receiving surface 33P, faces the same side as the plastic back surface 80r.

The second light receiving element 30Q has an element main surface 30Qs and an element back surface 30Qr facing opposite sides in the thickness direction of the second light receiving element 30Q. The element main surface 30Qs faces the same side as a pad main surface 52Ds of the die pad portion 52DB, and the element back surface 30Qr faces the same side as a pad back surface 52Dr. The element main surface 30Qs includes the light receiving surface 33Q. Therefore, in the present embodiment, the element back surface 30Qr forms a “back surface facing opposite side the light receiving surface”. Further, the element main surface 30Qs faces the same side as the plastic main surface 80s of the sealing plastic 80, and the element back surface 30Qr faces the same side as the plastic back surface 80r of the sealing plastic 80. That is, the light receiving surface 33Q faces the same side as the plastic main surface 80s, and the element back surface 20Qr of the second light emitting element 20Q, which is a light emitting surface facing the light receiving surface 33Q, faces the same side as the plastic back surface 80r.

The light of the first wavelength of the first light emitting element 20P and the light of the second wavelength of the second light emitting element 20Q can be changed. In one example, both the first light emitting element 20P and the second light emitting element 20Q may be formed to emit visible light. For example, the first light emitting element 20P may be formed to emit light having a wavelength including blue, and the second light emitting element 20Q may be formed to emit light having a wavelength including red. In the present embodiment, the light having the first wavelength of the first light emitting element 20P and the light having the second wavelength of the second light emitting element 20Q are light having different wavelengths, but the present invention is not limited thereto. The first light emitting element 20P and the second light emitting element 20Q may be formed to emit light of the same wavelength. In one example, both the first light emitting element 20P and the second light emitting element 20Q are formed to emit light including a red wavelength. In another example, both the first light emitting element 20P and the second light emitting element 20Q are formed to emit light having a wavelength including infrared rays.

Next, the cross-sectional structures of the die pad portion 52DB, the second light emitting element 20Q, and the second light receiving element 30Q, and the arrangements of the die pad portion 52DB, the second light receiving element 30Q, and the second light emitting element 20Q will be described using the cross-sectional structure of the insulation module 10 in FIGS. 3 to 8. The configurations of the die pad portion 42DB, the first light emitting element 20P, and the first light receiving element 30P, and the arrangements of the die pad portion 42DB, the first light receiving element 30P, and the first light emitting element 20P are similar to those of the second light emitting element 20Q, the second light receiving element 30Q, and the die pad portion 52DB, and thus, the detailed description thereof will be omitted. For the sake of convenience, the internal structures of the second light emitting element 20Q and the second light receiving element 30Q are omitted.

As illustrated in FIG. 3, the die pad portion 52DB is disposed closer to the plastic back surface 80r than the position where the terminal 51D protrudes from the second plastic side surface 82 in the z-direction. Therefore, the lead portion 52DA has a portion bent toward the plastic back surface 80r toward the die pad portion 52DB. The die pad portion 52DB has a pad main surface 52Ds and a pad back surface 52Dr facing opposite sides in the thickness direction. The pad main surface 52Ds is a surface forming a mounting surface on which the second light receiving element 30Q is mounted, and faces the same side as the plastic main surface 80s. The pad back surface 52Dr faces the same side as the plastic back surface 80r. The pad back surface 52Dr is disposed away from the plastic back surface 80r in the z-direction. That is, the pad back surface 52Dr is not exposed from the plastic back surface 80r.

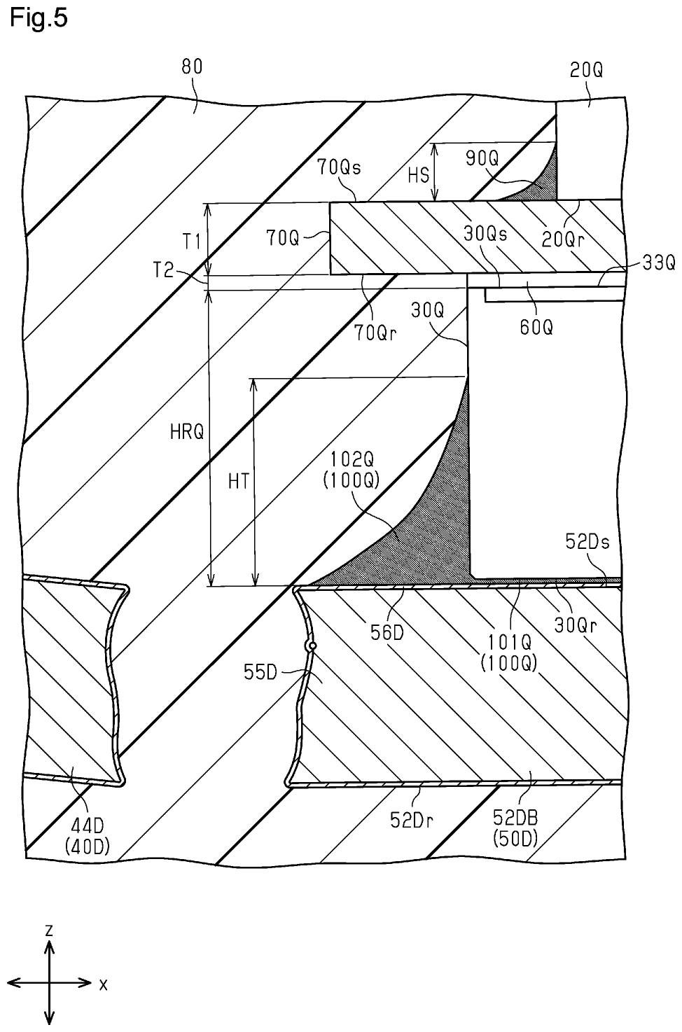

As illustrated in FIG. 5, the die pad portion 52DB includes a main metal layer 55D and a plating layer 56D formed on an outer surface of the main metal layer 55D. The main metal layer 55D is formed of, for example, a metal material containing Cu. The plating layer 56D is formed of a material containing nickel (Ni), chromium (Cr), or the like. As shown in FIG. 5, the plating layer 56D is sufficiently thinner than the main metal layer 55D.

A conductive bonding material 100Q, which bonds the second light receiving element 30Q and the die pad portion 52DB to each other, includes a first bonding region 101Q interposed between the element back surface 30Qr of the second light receiving element 30Q and the pad main surface 52Ds of the die pad portion 52DB, and a second bonding region 102Q protruding from the second light receiving element 30Q when viewed from the z-direction and bonded to an outer surface of the second light receiving element 30Q.

The second bonding region 102Q is provided such that the thickness of the second bonding region 102Q decreases as the distance from the outer surface of the second light receiving element 30Q increases. The second bonding region 102Q is formed over the entire circumference of the second light receiving element 30Q when viewed from the z-direction.

A height HT of a portion of the second bonding region 102Q in contact with the outer surface of the second light receiving element 30Q is greater than ½ or less of a height HRQ of the second light receiving element 30Q. In the present embodiment, the height HT is about ⅔ of the height HRQ. The height HT is defined by the height of a portion of the second bonding region 102Q in contact with the outer surface of the second light receiving element 30Q from the pad main surface 52Ds of the die pad portion 52DB. That is, the height HT can also be said as a thickness of a portion of the second bonding region 102Q in contact with the outer surface of the second light receiving element 30Q. Further, the height HRQ is defined by a distance between the pad main surface 52Ds of the die pad portion 52DB and the element main surface 30Qs of the second light receiving element 30Q in the z-direction. As described above, the portion of the second bonding region 102Q in contact with the outer surface of the second light receiving element 30Q is formed to be closer to the light receiving surface 33Q than the center of the second light receiving element 30Q in the thickness direction.

Similarly to the conductive bonding material 100Q, the conductive bonding material 100P which bonds the first light receiving element 30P and the die pad portion 42DB has a first bonding region 101P and a second bonding region 102P (see FIG. 6). The first bonding region 101P is interposed between the element back surface 30Pr of the first light receiving element 30P and the pad main surface 42DB of the die pad portion 42DB. The second bonding region 102P is a region protruding from the first light receiving element 30P when viewed from the z-direction, and is bonded to the outer surface of the first light receiving element 30P. Since the first bonding region 101P and the second bonding region 102P are similar to the conductive bonding material 100Q, the detailed description thereof will be omitted.

As illustrated in FIG. 6, the insulation module 10 includes a first plate-shaped member 70P stacked on the first light receiving element 30P, a second plate-shaped member 70Q stacked on the second light receiving element 30Q, a first transparent plastic 60P interposed between the first plate-shaped member 70P and the first light receiving element 30P, and a second transparent plastic 60Q interposed between the second plate-shaped member 70Q and the second light receiving element 30Q. In the present embodiment, both the first plate-shaped member 70P and the second plate-shaped member 70Q correspond to an “insulation member”. Both the first plate-shaped member 70P and the second plate-shaped member 70Q have translucency.

The first light emitting element 20P is disposed on the first plate-shaped member 70P, and the second light emitting element 20Q is disposed on the second plate-shaped member 70Q. That is, the first plate-shaped member 70P and the first transparent plastic 60P are interposed between the first light emitting element 20P and the first light receiving element 30P in the z-direction, and the second plate-shaped member 70Q and the second transparent plastic 60Q are interposed between the second light emitting element 20Q and the second light receiving element 30Q in the z-direction.

The first transparent plastic 60P is formed on the element main surface 30Ps of the first light receiving element 30P. At least a part of the first transparent plastic 60P is provided on the light receiving surface 33P. In the present embodiment, the first transparent plastic 60P is formed over the entire element main surface 30Ps, for example. The first transparent plastic 60P is a bonding material that bonds the first plate-shaped member 70P to the element main surface 30Ps of the first light receiving element 30P.

The second transparent plastic 60Q is formed on the element main surface 30Qs of the second light receiving element 30Q. At least a part of the second transparent plastic 60Q is provided on the light receiving surface 33Q. In the present embodiment, the second transparent plastic 60Q is formed over the entire element main surface 30Qs, for example. The second transparent plastic 60Q is a bonding material that bonds the second plate-shaped member 70Q to the element main surface 30Qs of the second light receiving element 30Q.

Each of the transparent plastics 60P and 60Q is made of an insulation material such as a transparent epoxy resin, an acrylic resin, a silicone resin, or the like. In the present embodiment, the first transparent plastic 60P is formed of an insulation plastic capable of transmitting light (light having the first wavelength) from the first light emitting element 20P. Preferably, the first transparent plastic 60P is formed of an insulation plastic that shields (does not transmit) light from the second light emitting element 20Q. The second transparent plastic 60Q is formed of an insulation plastic capable of transmitting light (light having the second wavelength) from the second light emitting element 20Q. Preferably, the second transparent plastic 60Q is formed of an insulation plastic that shields (does not transmit) light from the first light emitting element 20P. Each of the transparent plastics 60P and 60Q is formed by, for example, potting.

The first plate-shaped member 70P has a main surface 70Ps and a back surface 70Pr facing opposite sides in the thickness direction. The main surface 70Ps faces the same side as the element main surface 30Ps of the first light receiving element 30P, and the back surface 70Pr faces the same side as the element back surface 30Pr of the first light receiving element 30P. The first plate-shaped member 70P is in contact with the first transparent plastic 60P on the back surface 70Pr. In the present embodiment, the main surface 70Ps of the first plate-shaped member 70P corresponds to the “first surface”, and the back surface 70Pr corresponds to the “second surface”.

As illustrated in FIG. 2, the first plate-shaped member 70P is disposed so as to overlap the first semiconductor region of the first light receiving element 30P. The first plate-shaped member 70P covers the light receiving surface 33P of the first light receiving element 30P. The first plate-shaped member 70P is at least stacked on the light receiving surface 33P (see FIG. 2) of the first light receiving element 30P. Therefore, the back surface 70Pr of the first plate-shaped member 70P faces the light receiving surface 33P.

In the present embodiment, the first plate-shaped member 70P is shifted in the x-direction with respect to the first light receiving element 30P. More specifically, the first plate-shaped member 70P is disposed closer to the second plastic side surface 82 than the first light receiving element 30P. The first plate-shaped member 70P is disposed closer to the second plastic side surface 82 than the wires WB1 to WB4. In one example, the length of the first plate-shaped member 70P in the y-direction is longer than the length of the first light receiving element 30P in the y-direction.

As illustrated in FIG. 4, a thickness T1 of the second plate-shaped member 70Q is greater than a thickness T2 of the second transparent plastic 60Q. In other words, the thickness T2 of the second transparent plastic 60Q is less than the thickness T1 of the second plate-shaped member 70Q. The thickness T1 of the second plate-shaped member 70Q is, for example, twice or more and five times or less the thickness T2 of the second transparent plastic 60Q. In the present embodiment, the thickness T1 of the second plate-shaped member 70Q is about four times the thickness T2 of the second transparent plastic 60Q. The relationship between the thickness of the first plate-shaped member 70P and the thickness of the first transparent plastic 60P is the same as the relationship between the thickness T1 of the second plate-shaped member 70Q and the thickness T2 of the second transparent plastic 60Q.

As illustrated in FIG. 2, the first plate-shaped member 70P can be divided into a first extending portion 71P, a second extending portion 72P, and an intermediate portion 73P in the x-direction. The intermediate portion 73P is provided between the first extending portion 71P and the second extending portion 72P in the x-direction, and connects the first extending portion 71P and the second extending portion 72P. The first extending portion 71P is a portion protruding closer to the first plastic side surface 81 with respect to the first light emitting element 20P when viewed from the z-direction. The second extending portion 72P is a portion protruding closer to the second plastic side surface 82 than the first light emitting element 20P when viewed from the z-direction. The second extending portion 72P is a portion protruding toward the second semiconductor region of the first light receiving element 30P with respect to the first light emitting element 20P when viewed from the z-direction. The second extending portion 72P covers a part of the second semiconductor region of the first light receiving element 30P. The intermediate portion 73P is a portion overlapping the first light emitting element 20P when viewed from the z-direction. That is, the intermediate portion 73P is a portion corresponding to the first light emitting element 20P in the x-direction.

Both the first extending portion 71P and the intermediate portion 73P cover the first semiconductor region (light receiving surface 33P) of the first light receiving element 30P. The first extending portion 71P has a portion protruding closer to the second plastic side surface 82 than the first light receiving element 30P. In the present embodiment, the first extending portion 71P does not protrude in the x-direction with respect to the die pad portion 42DB. That is, the side surface closer to the second plastic side surface 82 of the opposite side surfaces in the x-direction of the first extending portion 71P is located closer to the first plastic side surface 81 than the side surface closer to the second plastic side surface 82 of the opposite side surfaces in the x-direction of the die pad portion 42DB when viewed from the z-direction. In the present embodiment, the length of the first extending portion 71P in the x-direction is longer than the length of the second extending portion 72P in the x-direction.

The length of the first extending portion 71P in the x-direction can be changed. In one example, the first extending portion 71P may be provided so as to protrude closer to the second plastic side surface 82 than the die pad portion 42DB when viewed from the z-direction. Further, the length of the first extending portion 71P in the x-direction may be equal to the length of the second extending portion 72P in the x-direction. The length of the first extending portion 71P in the x-direction may be shorter than the length of the second extending portion 72P in the x-direction.

As illustrated in FIGS. 4 and 5, the second plate-shaped member 70Q has a main surface 70Qs and a back surface 70Qr facing opposite sides in the thickness direction. The main surface 70Qs faces the same side as the element main surface 30Qs of the second light receiving element 30Q, and the back surface 70Qr faces the same side as the element back surface 30Qr of the second light receiving element 30Q. The second plate-shaped member 70Q is in contact with the second transparent plastic 60Q on the back surface 70Qr. In the present embodiment, the main surface 70Qs of the second plate-shaped member 70Q corresponds to the “first surface”, and the back surface 70Qr corresponds to the “second surface”.

As illustrated in FIG. 2, the second plate-shaped member 70Q is disposed so as to overlap the first semiconductor region of the second light receiving element 30Q. The second plate-shaped member 70Q covers the light receiving surface 33Q of the second light receiving element 30Q. The second plate-shaped member 70Q is at least stacked on the light receiving surface 33Q (see FIG. 2) of the second light receiving element 30Q. Therefore, the back surface 70Qr of the second plate-shaped member 70Q faces the light receiving surface 33Q.

In the present embodiment, the second plate-shaped member 70Q is shifted in the x-direction with respect to the second light receiving element 30Q. More specifically, the second plate-shaped member 70Q is disposed closer to the first plastic side surface 81 than the second light receiving element 30Q. The second plate-shaped member 70Q is disposed closer to the first plastic side surface 81 than the wires WC1 to WC3.

The second plate-shaped member 70Q can be divided into a first extending portion 71Q, a second extending portion 72Q, and an intermediate portion 73Q in the x-direction. The intermediate portion 73Q is provided between the first extending portion 71Q and the second extending portion 72Q in the x-direction, and connects the first extending portion 71Q and the second extending portion 72Q. The first extending portion 71Q is a portion protruding closer to the first plastic side surface 81 than the second light emitting element 20Q when viewed from the z-direction. The second extending portion 72Q is a portion protruding closer to the second plastic side surface 82 than the second light emitting element 20Q when viewed from the z-direction. The second extending portion 72Q is a portion protruding toward the second semiconductor region of the second light receiving element 30Q with respect to the second light emitting element 20Q when viewed from the z-direction. The second extending portion 72Q covers a part of the second semiconductor region of the second light receiving element 30Q. The intermediate portion 73Q is a portion overlapping the second light emitting element 20Q when viewed from the z-direction. That is, the intermediate portion 73Q is a portion corresponding to the second light emitting element 20Q in the x-direction.

Both the first extending portion 71Q and the intermediate portion 73Q cover the first semiconductor region (light receiving surface 33Q) of the second light receiving element 30Q. The first extending portion 71Q has a portion protruding closer to the first plastic side surface 81 than the second light receiving element 30Q. In the present embodiment, the first extending portion 71Q does not protrude in the x-direction with respect to the die pad portion 52DB. That is, the side surface closer to the first plastic side surface 81 of the opposite side surfaces of the first extending portion 71Q in the x-direction is located closer to the second plastic side surface 82 than the side surface closer to the first plastic side surface 81 of the opposite side surfaces of the die pad portion 52DB in the x-direction when viewed from the z-direction. In the present embodiment, the length of the first extending portion 71Q in the x-direction is longer than the length of the second extending portion 72Q in the x-direction.

The length of the first extending portion 71Q in the x-direction can be changed. In one example, the first extending portion 71Q may be provided so as to protrude closer to the first plastic side surface 81 than the die pad portion 52DB when viewed from the z-direction. Further, the length of the first extending portion 71Q in the x-direction may be equal to the length of the second extending portion 72Q in the x-direction. The length of the first extending portion 71Q in the x-direction may be shorter than the length of the second extending portion 72Q in the x-direction.

In the present embodiment, the light transmittance of the first plate-shaped member 70P is lower than the light transmittance of the first transparent plastic 60P. The first plate-shaped member 70P is formed such that the light transmittance thereof is lower than the light transmittance of the first transparent plastic 60P. In one example, a material whose light transmittance is lower than the light transmittance of the first transparent plastic 60P is used as the material of the first plate-shaped member 70P. The same applies to the relationship between the second plate-shaped member 70Q and the second transparent plastic 60Q.

The light transmittance of the first plate-shaped member 70P can be changed. In one example, the light transmittance of the first plate-shaped member 70P may be equal to the light transmittance of the first transparent plastic 60P, or may be greater than the light transmittance of the first transparent plastic 60P. That is, the light transmittance of the first plate-shaped member 70P may be greater than or equal to the light transmittance of the first transparent plastic 60P. In other words, the light transmittance of the first transparent plastic 60P may be equal to or less than the light transmittance of the first plate-shaped member 70P. The relationship between the second plate-shaped member 70Q and the second transparent plastic 60Q may be similarly changed.

The thickness of the first plate-shaped member 70P, the thickness T1 of the second plate-shaped member 70Q, the thickness of the first transparent plastic 60P, and the thickness T2 of the second transparent plastic 60Q can be changed. In one example, the thickness of the first plate-shaped member 70P may be equal to the thickness of the first transparent plastic 60P. In another example, the thickness of the first plate-shaped member 70P may be less than the thickness of the first transparent plastic 60P. In other words, the thickness of the first transparent plastic 60P may be greater than the thickness of the first plate-shaped member 70P. That is, the thickness of the first transparent plastic 60P may be greater than or equal to the thickness of the first plate-shaped member 70P. In one example, the thickness T1 of the second plate-shaped member 70Q may be equal to the thickness T2 of the second transparent plastic 60Q. In another example, the thickness T1 of the second plate-shaped member 70Q may be less than the thickness T2 of the second transparent plastic 60Q. In other words, the thickness T2 of the second transparent plastic 60Q may be greater than the thickness T1 of the second plate-shaped member 70Q. That is, the thickness T2 of the second transparent plastic 60Q may be greater than or equal to the thickness T1 of the second plate-shaped member 70Q.

In addition, the first plate-shaped member 70P is formed of an insulation plastic capable of transmitting light (light having the first wavelength) from the first light emitting element 20P. The first plate-shaped member 70P may be formed of an insulation plastic that shields (does not transmit) light from the second light emitting element 20Q. The second plate-shaped member 70Q is formed of an insulation plastic capable of transmitting light (light having the second wavelength) from the second light emitting element 20Q. The second plate-shaped member 70Q may be formed of an insulation plastic that shields (does not transmit) light from the first light emitting element 20P. In this case, each of the transparent plastics 60P and 60Q may be formed of a plastic material capable of transmitting both light having the first wavelength and light having the second wavelength.

As illustrated in FIG. 6, the first light emitting element 20P is disposed on the main surface 70Ps of the first plate-shaped member 70P. More specifically, the element back surface 20Pr of the first light emitting element 20P is in contact with the main surface 70Ps of the first plate-shaped member 70P. The first transparent plastic 60P is formed on the first light receiving element 30P, and the first plate-shaped member 70P is disposed on the first transparent plastic 60P. As described above, since the first plate-shaped member 70P is stacked on the first light receiving element 30P having the first transparent plastic 60P in between, and the first light emitting element 20P is stacked on the first plate-shaped member 70P, the first light emitting element 20P is stacked on the first light receiving element 30P.

The first light emitting element 20P is bonded to the first plate-shaped member 70P, for example, an insulation bonding material 90P. In a state where the first light emitting element 20P is disposed on the main surface 70Ps of the first plate-shaped member 70P, the insulation bonding material 90P is applied so as to be in contact with the first light emitting element 20P and the main surface 70Ps of the first plate-shaped member 70P, whereby the first light emitting element 20P is bonded to the first plate-shaped member 70P. Therefore, the insulation bonding material 90P is not interposed between the element back surface 20Pr of the first light emitting element 20P and the main surface 70Ps of the first plate-shaped member 70P. In the present embodiment, the insulation bonding material 90P corresponds to a “bonding material for light emission”.

The second light emitting element 20Q is disposed on the main surface 70Qs of the second plate-shaped member 70Q. More specifically, the element back surface 20Qr of the second light emitting element 20Q is in contact with the main surface 70Qs of the second plate-shaped member 70Q. As described above, since the second plate-shaped member 70Q is stacked on the second light receiving element 30Q, and the second light emitting element 20Q is stacked on the second plate-shaped member 70Q, the second light emitting element 20Q is stacked on the second light receiving element 30Q.

The second light emitting element 20Q is bonded to the second plate-shaped member 70Q by, for example, an insulation bonding material 90Q. In a state where the second light emitting element 20Q is disposed on the main surface 70Qs of the second plate-shaped member 70Q, the insulation bonding material 90Q is applied so as to be in contact with the second light emitting element 20Q and the main surface 70Qs of the second plate-shaped member 70Q, whereby the second light emitting element 20Q is bonded to the second plate-shaped member 70Q. Therefore, the insulation bonding material 90Q is not interposed between the element back surface 20Qr of the second light emitting element 20Q and the main surface 70Qs of the second plate-shaped member 70Q. In the present embodiment, the insulation bonding material 90Q corresponds to a “bonding material for light emission”.

For example, a light-shielding material containing a plastic material as a main component is used as the insulation bonding materials 90P and 90Q. An example of such a material is an epoxy resin. That is, as an example, the insulation bonding materials 90P and 90Q may be formed of a plastic material that absorbs light.

As illustrated in FIG. 6, the insulation bonding material 90Q is in contact with the outer surface of the second light emitting element 20Q and the main surface 70Qs of the second plate-shaped member 70Q, and is provided such that the thickness of the insulation bonding material 90Q decreases as the distance from the outer surface of the second light emitting element 20Q increases. The insulation bonding material 90Q is formed over the entire circumference of the second light emitting element 20Q when viewed from the z-direction.

As illustrated in FIG. 4, a height HS of the portion of the insulation bonding material 90Q in contact with the outer surface of the second light emitting element 20Q is ½ or less of a height HDQ of the second light emitting element 20Q. In the present embodiment, the height HS of the insulation bonding material 90Q is smaller than ½ of the height HDQ. The height HS is defined by the height of a portion of the insulation bonding material 90Q in contact with the outer surface of the second light emitting element 20Q from the pad main surface 52Ds of the die pad portion 52DB. That is, the height HS is the thickness of the portion of the insulation bonding material 90Q in contact with the outer surface of the second light emitting element 20Q. The height HDQ of the second light emitting element 20Q is defined by the distance between the pad main surface 52Ds of the die pad portion 52DB and the element main surface 20Qs of the second light emitting element 20Q in the z-direction.

As illustrated in FIG. 5, the height HS of the insulation bonding material 90Q is smaller than the height HT of the conductive bonding material 100Q. The height HT (thickness) of the conductive bonding material 100Q is greater than the thickness T1 of the second plate-shaped member 70Q. The height HS (thickness) of the insulation bonding material 90Q is greater than the thickness T2 of the second transparent plastic 60Q.

As illustrated in FIG. 3, the thickness of the second light emitting element 20Q (dimension of the second light emitting element 20Q in the z-direction) is less than the thickness of the second light receiving element 30Q (dimension of the second light receiving element 30Q in the z-direction). In the present embodiment, the thickness of the second light emitting element 20Q is 80% or more and 90% or less of the thickness of the second light receiving element 30Q. The thickness of the second light emitting element 20Q is defined by the distance between the element main surface 20Qs and the element back surface 20Qr in the thickness direction of the second light emitting element 20Q. The thickness of the second light receiving element 30Q is defined by the distance between the element main surface 30Qs and the element back surface 30Qr in the thickness direction of the second light receiving element 30Q.

The relationship between the thickness of the second light emitting element 20Q and the thickness of the second light receiving element 30Q can be changed. In one example, the thickness of the second light emitting element 20Q is greater than 90% and less than 100% of the thickness of the second light receiving element 30Q. The thickness of the second light emitting element 20Q may be 70% or more and less than 80% of the thickness of the second light receiving element 30Q. In one example, the thickness of the second light emitting element 20Q may be 60% or more and less than 70% of the thickness of the second light receiving element 30Q. In one example, the thickness of the second light emitting element 20Q may be 50% or more and less than 60% of the thickness of the second light receiving element 30Q. The thickness of the second light emitting element 20Q is greater than the thickness of the second plate-shaped member 70Q. In other words, the thickness of the second plate-shaped member 70Q is less than the thickness of the second light emitting element 20Q.

A first electrode 21Q and a second electrode 22Q are provided on the element back surface 20Qr of the second light emitting element 20Q. A first electrode 21P and a second electrode 22P are provided on an element back surface 20Pr (see FIG. 6) of the first light emitting element 20P. In the present embodiment, the first electrode 21Q and the second electrode 22Q each correspond to a “pad”. The first electrode 21P and the second electrode 22P each correspond to a “pad”.

As illustrated in FIG. 6, the sealing plastic 80 covers each of the light emitting elements 20P and 20Q, the light receiving elements 30P and 30Q, the plate-shaped members 70P and 70Q, the transparent plastics 60P and 60Q, and the die pad portions 42DB and 52DB. The sealing plastic 80 has a separation wall portion 89 interposed between the first light emitting element 20P, the first plate-shaped member 70P, the first transparent plastic 60P, the first light receiving element 30P and the die pad portion 42DB, and the second light emitting element 20Q, the second plate-shaped member 70Q, the second transparent plastic 60Q, the second light receiving element 30Q, and the die pad portion 52DB in the y-direction. The separation wall portion 89 shields light between the first light emitting element 20P, the first plate-shaped member 70P, the first transparent plastic 60P, the first light receiving element 30P and the die pad portion 42DB, and the second light emitting element 20Q, the second plate-shaped member 70Q, the second transparent plastic 60Q, the second light receiving element 30Q and the die pad portion 52DB.

Next, an electrical connection relationship among each of the light emitting elements 20P and 20Q, the light receiving elements 30P and 30Q, the first lead frame 40, and the second lead frame 50 will be described with reference to FIG. 2.

As illustrated in FIG. 2, the first light emitting element 20P is electrically connected to the second lead frame 50D and the second light receiving element 30Q, and the second light emitting element 20Q is electrically connected to the first lead frame 40D and the first light receiving element 30P.

The first electrode 21P of the first light emitting element 20P is connected to the second light receiving element 30Q by one wire WA1. As a result, the first electrode 21P and the second light receiving element 30Q are electrically connected.

The second electrode 22P of the first light emitting element 20P is connected to the second lead frame 50D by one wire WA2. As a result, the second electrode 22P and the second lead frame 50D are electrically connected. The wire WA2 connects the second electrode 22P and the wire connection portion 52DC of the second lead frame 50D.

The first electrode 21Q of the second light emitting element 20Q is connected to the first light receiving element 30P by one wire WA3. As a result, the first electrode 21Q and the first light receiving element 30P are electrically connected.

The second electrode 22Q of the second light emitting element 20Q is connected to a second portion 44D of the lead portion 42DA in the first lead frame 40D by one wire WA4. As a result, the second electrode 22Q and the first lead frame 40D are electrically connected. The wire WA4 is connected to a portion of the second portion 44D of the lead portion 42DA overlapping the second light receiving element 30Q when viewed from the x-direction.

The first light receiving element 30P is electrically connected to the first lead frames 40A to 40D by wires WB1 to WB4. The second light receiving element 30Q is electrically connected to the second lead frames 50A to 50C by WC1 to WC3.

The wire WB1 connects the second semiconductor region of the first light receiving element 30P and the wire connection portion 42AB of the first lead frame 40A. The wire WB2 connects the second semiconductor region of the first light receiving element 30P and the wire connection portion 42BB of the first lead frame 40B. The wire WB3 connects the second semiconductor region of the first light receiving element 30P and the wire connection portion 42CB of the first lead frame 40C. The wire WB4 connects the second semiconductor region of the first light receiving element 30P and the second portion 44D of the lead portion 42DA. The wires WB1 to WB4 are connected to the outer peripheral portion of the second semiconductor region of the first light receiving element 30P when viewed from the z-direction.

The wire WC1 connects the second semiconductor region of the second light receiving element 30Q and the wire connection portion 52AB of the second lead frame 50A. The wire WC2 connects the second semiconductor region of the second light receiving element 30Q and the wire connection portion 52BB of the second lead frame 50B. The wire WC3 connects the second semiconductor region of the second light receiving element 30Q and the wire connection portion 52CB of the second lead frame 50C. The wire WC4 connects the second semiconductor region of the second light receiving element 30Q and the wire connection portion 53D of the lead portion 52DA. The wires WC1 to WC4 are connected to the outer peripheral portion of the second semiconductor region of the second light receiving element 30Q when viewed from the z-direction.

The wires WA1 to WA4, WB1 to WB4, and WC1 to WC4 are formed of, for example, a conductive material such as Cu, aluminum (Al), gold (Au), Ag, or the like. In the present embodiment, the wires WA1 to WA4, WB1 to WB4, and WC1 to WC4 are formed of a material containing Au.

Internal Structure of Light Emitting Element

Next, an outline of an internal structure of the first light emitting element 20P will be described with reference to FIG. 7. Since the internal structure of the second light emitting element 20Q is similar to the internal structure of the first light emitting element 20P, the detailed description thereof will be omitted.

FIG. 7 is a cross-sectional view schematically illustrating an internal structure of the first light emitting element 20P.

The first light emitting element 20P includes a substrate 23P, a first contact layer 24P formed on the substrate 23P, an active layer 25P having a quantum well structure formed on the first contact layer 24P, a second contact layer 26P formed on the active layer 25P, and a reflection layer 27P formed on the second contact layer 26P. The first light emitting element 20P includes the first electrode 21P formed on the reflection layer 27P and the second electrode 22P formed on the first contact layer 24P. Therefore, in the present embodiment, the first electrode 21P forms an anode electrode, and the second electrode 22P forms a cathode electrode. In the present embodiment, the active layer 25P corresponds to a “light emitting layer”.

In the present embodiment, a sapphire substrate having translucency is used as the substrate 23P. However, the substrate 23P is not limited to the sapphire substrate, and a substrate of another material may be used as long as it has translucency. The substrate 23P forms the element back surface 20Qr (see FIG. 6) of the first light emitting element 20P. That is, a substrate back surface forming the element back surface 20Pr of the substrate 23P forms the light emitting surface of the first light emitting element 20P, and is in contact with the main surface 70Ps of the first plate-shaped member 70P. In addition, the insulation bonding material 90P (see FIG. 6) is in contact with a side surface of the substrate 23P forming the outer surface of the first light emitting element 20P. Therefore, the substrate 23P and the first plate-shaped member 70P are bonded by the insulation bonding material 90P.

Both the first contact layer 24P and the second contact layer 26P are made of a nitride semiconductor, and are n-type GaN layers in one example. The first contact layer 24P and the second contact layer 26P have different thicknesses. The second contact layer 26P is thinner than the first contact layer 24P. In one example, the thickness of the first contact layer 24P is in a range of 1 μm to 5 μm, and the thickness of the second contact layer 26P is in a range of 0.2 μm to 1 μm.

The active layer 25P has a quantum well structure including a well layer and a barrier layer having a band gap greater than that of the well layer and sandwiching the well layer. The active layer 25P may have a multiple quantum well (MQW) structure, and in this case, the active layer 25P includes multiple quantum well structures. In one example, the active layer 25P includes multiple AlBInGaN layers having different compositions, and the In composition ratio of the barrier layer is smaller than that of the well layer such that the barrier layer has a greater band gap than that of the well layer.

The reflection layer 27P is a layer that reflects light passing from the active layer 25P through the second contact layer 26P. The reflection layer 27P is formed of a metal material such as Ag, Al, Au or the like. In the present embodiment, the reflection layer 27P is formed of Au. The light reflected by the reflection layer 27P passes through the second contact layer 26P, the active layer 25P, the first contact layer 24P, and the substrate 23P, and is emitted to the outside of the first light emitting element 20P.

The reflection layer 27P is provided on the side opposite to the substrate 23P with respect to the active layer 25P. Therefore, the reflection layer 27P is provided closer to the element main surface 20Ps (back surface of the first light emitting element 20P) of the first light emitting element 20P than the active layer 25P.

Internal Structure of Light Receiving Element

Next, an internal structure of the first light receiving element 30P will be described with reference to FIG. 8. Since the cross-sectional structure of the second light receiving element 30Q is similar to the internal structure of the first light receiving element 30P, the detailed description thereof will be omitted.

FIG. 8 is a cross-sectional view schematically illustrating a cross-sectional structure of element main surface 30Ps of first light receiving element 30P and its periphery.

As illustrated in FIG. 8, the first light receiving element 30P includes a semiconductor substrate 34P, an insulation wiring layer 35PC formed on a front surface 34Ps of the semiconductor substrate 34P, and an insulation layer 36P stacked on the insulation wiring layer 35PC.

The semiconductor substrate 34P forms an element back surface 30Pr (see FIG. 6) of the first light receiving element 30P. That is, a back surface (not illustrated) of the semiconductor substrate 34P facing the side opposite to the front surface 34Ps forms the element back surface 30Pr. As the semiconductor substrate 34P, for example, a substrate formed of a material containing silicon (Si) is used. A photoelectric conversion element 35PA is provided in a first semiconductor region 34PA of the semiconductor substrate 34P. A control circuit 35PB is provided in a second semiconductor region 34PB of the semiconductor substrate 34P. The control circuit 35PB is, for example, a circuit that receives a signal from the photoelectric conversion element 35PA. As described above, the photoelectric conversion element 35PA and the control circuit 35PB are provided side by side in a direction orthogonal to the thickness direction of the first light receiving element 30P.

The insulation wiring layer 35PC includes wiring that electrically connects the photoelectric conversion element 35PA and the control circuit 35PB. The insulation wiring layer 35PC is formed so as to overlap both the photoelectric conversion element 35PA and the control circuit 35PB when viewed from the z-direction.

The insulation layer 36P is stacked on the photoelectric conversion element 35PA and the control circuit 35PB. That is, the insulation layer 36P is provided over both the first semiconductor region 34PA and the second semiconductor region 34PB of the semiconductor substrate 34P. In the present embodiment, the insulation layer 36P is formed over the entire insulation wiring layer 35PC.

The insulation layer 36P includes a first insulation portion 36PA formed on the photoelectric conversion element 35PA and a second insulation portion 36PB formed on the control circuit 35PB. The first insulation portion 36PA is a portion corresponding to the first semiconductor region 34PA, and the second insulation portion 36PB is a portion corresponding to the second semiconductor region 34PB. A front surface 36Ps of insulation layer 36P forms the element main surface 30Ps. A portion of the front surface 36Ps of the insulation layer 36P corresponding to the first insulation portion 36PA forms the light receiving surface 33P.

The insulation layer 36P includes multiple insulation films 37PA to 37PE stacked on each other in the z-direction, multiple wiring layers 38PA to 38PE provided in the insulation films 37PA to 37PE, and vias 39PA to 39PD connecting the wiring layers 38PA to 38PE. In the present embodiment, the multiple wiring layers 38PA to 38PE and the vias 39PA to 39PD are provided in the second insulation portion 36PB. In other words, in the present embodiment, the wiring layers 38PA to 38PE and the vias 39PA to 39PD are not provided in the first insulation portion 36PA. In the present embodiment, the wiring layers 38PA to 38PE provided in the second insulation portion 36PB correspond to the “first wiring layer”.

As illustrated in FIG. 8, the insulation films 37PA to 37PE are stacked on the insulation wiring layer 35PC in the given order. Each of the insulation films 37PA to 37PE is an interlayer insulation film, and is formed of, for example, silicon oxide (SiO₂).

In the present embodiment, the wiring layers 38PA to 38PE are layers in which wiring connected to the control circuit 35PB is mainly formed, and are provided in the second insulation portion 36PB of the insulation layer 36P. In other words, the wiring layers 38PA to 38PE are not provided in the first insulation portion 36PA of the insulation layer 36P. In the illustrated example, the wiring layers 38PA to 38PE are disposed so as to overlap each other when viewed from the z-direction. Each of the wiring layers 38PA to 38PE is formed of a metal material such as Al, Ti (titanium), or the like.

The wiring layer 38PA is embedded in the insulation film 37PA. The wiring layer 38PA is electrically connected to, for example, the semiconductor substrate 34P.

The wiring layer 38PB is embedded in the insulation film 37PB. The wiring layer 38PA and the wiring layer 38PB are connected by multiple vias 39PA. Each via 39PA is embedded in the insulation film 37PA and extends in the z-direction.

The wiring layer 38PC is embedded in the insulation film 37PC. The wiring layer 38PB and the wiring layer 38PC are connected by multiple vias 39PB. Each via 39PB is embedded in the insulation film 37PB and extends in the z-direction.

The wiring layer 38PD is embedded in the insulation film 37PD. The wiring layer 38PC and the wiring layer 38PD are connected by multiple vias 39PC. Each via 39PC is embedded in the insulation film 37PC and extends in the z-direction.

The wiring layer 38PE is embedded in the insulation film 37PE. The wiring layer 38PD and the wiring layer 38PE are connected by multiple vias 39PD. Each via 39PD is embedded in the insulation film 37PD and extends in the z-direction.

In the present embodiment, the wiring layers 38PA to 38PE are provided corresponding to the insulation films 37PA to 37PE, but the present invention is not limited thereto. The second insulation portion 36PB may have an insulation film on which no wiring layer is provided.

Configuration of Outer Peripheral Portion of Sealing Plastic

Next, a structure between terminals 41A to 41D and a structure between terminals 51A to 51D in the sealing plastic 80 will be described with reference to FIGS. 9 and 10. FIG. 9 is a plan view of the insulation module 10 illustrating each of the terminals 41A to 41D and a part of the sealing plastic 80, and FIG. 10 is a plan view of the insulation module 10 illustrating each of the terminals 51A to 51D and a part of the sealing plastic 80.

As illustrated in FIGS. 2 and 9, an uneven portion 87 is provided in a portion between terminals adjacent in the y-direction among the terminals 41A to 41D on the first plastic side surface 81 of the sealing plastic 80. Specifically, the uneven portion 87 is provided in each of a portion of the first plastic side surface 81 between the terminal 41A and the terminal 41B in the y-direction, a portion of the first plastic side surface 81 between the terminal 41B and the terminal 41C in the y-direction, and a portion of the first plastic side surface 81 between the terminal 41C and the terminal 41D in the y-direction. In the present embodiment, for example, the terminal 41B corresponds to the “first terminal” and the terminal 41C corresponds to the “second terminal” among the terminals 41A to 41D. The uneven portion 87 corresponds to a “first uneven portion”.

The uneven portion 87 is formed over the entire first plastic side surface 81 in the z-direction. Each uneven portion 87 includes the first plastic side surface 81 and a recessed section 87a recessed from the first plastic side surface 81. Each uneven portion 87 has, for example, multiple recessed sections 87a. In the present embodiment, the uneven portion 87 provided between the terminal 41A and the terminal 41B in the y-direction has two recessed sections 87a. The uneven portion 87 provided between the terminal 41B and the terminal 41C in the y-direction has three recessed sections 87a. The uneven portion 87 provided between the terminal 41C and the terminal 41D in the y-direction has three recessed sections 87a.

Each recessed section 87a is provided so as to extend through the sealing plastic 80 in the z-direction. In the present embodiment, the bottom surface of each recessed section 87a is formed so as to be parallel to the first side surface 85 and the second side surface 86 of the first plastic side surface 81. That is, a portion of the bottom surface of each recessed section 87a corresponding to the first side surface 85 extends so as to be inclined toward the outside of the sealing plastic 80 in the x-direction from the plastic main surface 80s toward the plastic back surface 80r. A portion of the bottom surface of each recessed section 87a corresponding to the second side surface 86 extends so as to be inclined toward the outside of the sealing plastic 80 in the x-direction from the plastic back surface 80r toward the plastic main surface 80s.

The two recessed sections 87a of the uneven portion 87 provided between the terminal 41A and the terminal 41B in the y-direction are dispersedly provided in a portion between the terminal 41A and the suspension lead 46D in the y-direction and a portion between the suspension lead 46D and the terminal 41B in the y-direction. In this case, the suspension lead 46D corresponds to the “first terminal”, and the terminal 41A and the terminal 41B correspond to the “second terminal”.

As illustrated in FIGS. 2 and 10, an uneven portion 88 is provided in a portion between terminals adjacent in the y-direction among the terminals 51A to 51D on the second plastic side surface 82 of the sealing plastic 80. Specifically, the uneven portion 88 is provided in each of a portion of the second plastic side surface 82 between the terminal 51A and the terminal 51B in the y-direction, a portion of the second plastic side surface 82 between the terminal 51B and the terminal 51C in the y-direction, and a portion of the second plastic side surface 82 between the terminal 51C and the terminal 51D in the y-direction. In the present embodiment, any two of the terminals 51A to 51D correspond to the “first terminal” and the “second terminal”. The uneven portion 88 corresponds to a “first uneven portion”.

The uneven portion 88 is formed over the entire second plastic side surface 82 in the z-direction. Each uneven portion 88 includes the second plastic side surface 82 and a recessed section 88a recessed from the second plastic side surface 82. Each uneven portion 88 has, for example, multiple (three in the present embodiment) recessed section 88a. Each recessed section 88a is provided so as to extend through the sealing plastic 80 in the z-direction. In the present embodiment, the bottom surface of each recessed section 88a is formed so as to be parallel to the first side surface 85 and the second side surface 86 (see FIG. 3) of the second plastic side surface 82. That is, a portion of the bottom surface of each recessed section 88a corresponding to the first side surface 85 extends so as to be inclined toward the outside of the sealing plastic 80 in the x-direction from the plastic main surface 80s toward the plastic back surface 80r (both refer to FIG. 3). A portion of the bottom surface of each recessed section 88a corresponding to the second side surface 86 extends so as to be inclined toward the outside of the sealing plastic 80 in the x-direction from the plastic back surface 80r toward the plastic main surface 80s.

The bottom surfaces of the recessed sections 87a and 88a may be formed to extend along the z-direction. In addition, the number of recessed sections 87a and 88a of each of the uneven portions 87 and 88 can be changed. Each of the uneven portions 87 and 88 may have at least one of the recessed sections 87a and 88a. Further, the uneven portion 87 may have a projection protruding from the first plastic side surface 81 instead of the recessed section 87a. The uneven portion 88 may have a projection protruding from the second plastic side surface 82 instead of the recessed section 88a.

The number of uneven portions 87 can be changed. The uneven portion 87 may be provided on at least one of a portion of the first plastic side surface 81 between the terminals 41A and 41B in the y-direction, a portion of the first plastic side surface 81 between the terminals 41B and 41C in the y-direction, and a portion of the first plastic side surface 81 between the terminals 41C and 41D in the y-direction. In addition, it may be provided on at least one of a portion between the terminal 41A and the suspension lead 46D in the y-direction and a portion between the suspension lead 46D and the terminal 41B in the y-direction of the portion between the terminal 41A and the terminal 41B in the y-direction on the first plastic side surface 81.

Similarly, the number of uneven portions 88 can be changed. The uneven portion 88 may be provided on at least one of a portion of the second plastic side surface 82 between the terminal 51A and the terminal 51B in the y-direction, a portion of the second plastic side surface 82 between the terminal 51B and the terminal 51C in the y-direction, and a portion of the second plastic side surface 82 between the terminal 51C and the terminal 51D in the y-direction.

Electrical Configuration

FIG. 11 is a circuit diagram schematically illustrating a circuit configuration of the insulation module 10 and a connection configuration between the insulation module 10 and an inverter circuit 500.

The inverter circuit 500 of the present embodiment is a half-bridge type inverter circuit, and includes a first switching element 501 and a second switching element 502 connected in series with each other.

A positive electrode of a control power supply 503 is electrically connected to the terminal 51A of the insulation module 10. The terminal 51D of the insulation module 10 is electrically connected between a source of the first switching element 501 and a drain of the second switching element 502.

As illustrated in FIG. 11, the insulation module 10 includes a first light emitting diode 20AP, a second light emitting diode 20AQ, a first light receiving diode 30AP, a second light receiving diode 30AQ, a first control circuit 230A, and a second control circuit 230B. The first light emitting element 20P includes the first light emitting diode 20AP, and the second light emitting element 20Q includes the second light emitting diode 20AQ. The first light receiving element 30P includes the first light receiving diode 30AP, and the second light receiving element 30Q includes the second light receiving diode 30AQ.

The first light emitting diode 20AP includes the first electrode 21P and the second electrode 22P of the first light emitting element 20P, and the second light emitting diode 20AQ includes the first electrode 21Q and the second electrode 22Q of the second light emitting element 20Q. The first light receiving diode 30AP includes a first electrode 31P and a second electrode 32P of the first light receiving element 30P, and the second light receiving diode 30AQ includes a first electrode 31Q and a second electrode 32Q of the second light receiving element 30Q.

The first light emitting diode 20AP is electrically connected to the terminals 51A and 51D. Specifically, the first electrode 21P (anode electrode) of the first light emitting diode 20AP is electrically connected to the terminal 51A via a second current source 233B of the second control circuit 230B, and the second electrode 22P (cathode electrode) is electrically connected to the terminal 51D. The control power supply 503 is electrically connected to the terminal 51A. The control power supply 503 supplies a drive voltage to the first light emitting diode 20AP and the second control circuit 230B.

The first light receiving diode 30AP is electrically connected to the first control circuit 230A, and is insulated from the first light emitting diode 20AP. In other words, the first light emitting diode 20AP is insulated from the first control circuit 230A. On the other hand, the first light emitting diode 20AP is electrically connected to the second control circuit 230B. Both the first electrode 31P (anode electrode) and the second electrode 32P (cathode electrode) of the first light receiving diode 30AP are electrically connected to the first control circuit 230A. The first control circuit 230A is electrically connected to the terminals 41A to 41D.

The second light emitting diode 20AQ is connected to the terminals 41A and 41D. Specifically, the first electrode 21Q (anode electrode) of the second light emitting diode 20AQ is electrically connected to the terminal 41A via the first current source 233A of the first control circuit 230A, and the second electrode 22Q (cathode electrode) is electrically connected to the terminal 41D. A control power supply 504 is electrically connected to the terminal 41A. The control power supply 504 supplies a drive voltage to the second light emitting diode 20AQ and the first control circuit 230A.

The second light receiving diode 30AQ is electrically connected to the second control circuit 230B, and is insulated from the second light emitting diode 20AQ. In other words, the second light emitting diode 20AQ is insulated from the second control circuit 230B. On the other hand, the second light emitting diode 20AQ is electrically connected to the first control circuit 230A. Both the first electrode 31Q (anode electrode) and the second electrode 32Q (cathode electrode) of the second light receiving diode 30AQ are electrically connected to the second control circuit 230B. The second control circuit 230B is electrically connected to the terminals 51A to 51D.

As described above, the first light emitting diode 20AP and the first light receiving diode 30AP form a photocoupler that transmits a signal from the terminals 51A to 51D, i.e., the inverter circuit 500 to the terminals 41A to 41D. The second light emitting diode 20AQ and the second light receiving diode 30AQ form a photocoupler that transmits a signal from the terminals 41A to 41D to the terminals 51A to 51D. That is, the insulation module 10 of the present embodiment is configured to transmit signals bidirectionally. The terminals 41A to 41D and the terminals 51A to 51D are insulated from each other by a first photocoupler and a second photocoupler.

Next, the configuration of each of the control circuits 230A and 230B will be described.

The first control circuit 230A includes a first Schmitt trigger 231A, a first output unit 232A, a first current source 233A, and a first driver 234A. The first current source 233A and the first driver 234A form a drive unit that drives the second light emitting diode 20AQ. The first control circuit 230A generates an output signal based on a change in the voltage of the first light receiving diode 30AP caused when the first light receiving diode 30AP receives light from the first light emitting diode 20AP.

The first Schmitt trigger 231A is electrically connected to both the first electrode 31P and the second electrode 32P of the first light receiving diode 30AP. The first Schmitt trigger 231A is electrically connected to the terminals 41A and 41D. That is, power is supplied from the control power supply 504 to the first Schmitt trigger 231A. The first Schmitt trigger 231A transmits the voltage of the first light receiving diode 30AP to the first output unit 232A. A predetermined hysteresis is given to a threshold voltage of the first Schmitt trigger 231A. This configuration enhances the resistance to noise.

The first output unit 232A includes a first switching element 232Aa and a second switching element 232Ab connected in series to each other. In the example illustrated in FIG. 11, a p-type MOSFET is used as the first switching element 232Aa, and an n-type MOSFET is used as the second switching element 232Ab.

The source of the first switching element 232Aa is electrically connected to the terminal 41A. The source of the second switching element 232Ab is electrically connected to the terminal 41D. A node between the drain of the first switching element 232Aa and the drain of the second switching element 232Ab is electrically connected to the terminal 41B.

Both the gate of the first switching element 232Aa and the gate of the second switching element 232Ab are electrically connected to the first Schmitt trigger 231A. That is, the signal from the first Schmitt trigger 231A is applied to both the gate of the first switching element 232Aa and the gate of the second switching element 232Ab.

The first output unit 232A generates an output signal by complementarily turning on and off the first switching element 232Aa and the second switching element 232Ab based on the signal of the first Schmitt trigger 231A. The first output unit 232A outputs an output signal through the terminal 41B.

The first current source 233A is electrically connected between the terminal 41A and the first electrode 21Q of the second light emitting diode 20AQ. As a result, a constant current is supplied from the terminal 41A to the second light emitting diode 20AQ.

The first driver 234A is electrically connected to both the first current source 233A and the terminal 41C. The first driver 234A is a circuit that controls supply of a current to the second light emitting diode 20AQ. That is, the first driver 234A controls the supply of the current to the second light emitting diode 20AQ based on the control signal supplied from the outside of the insulation module 10 to the terminal 41C. In one example, when the control signal is input to the first driver 234A, the first driver 234A supplies a current to the second light emitting diode 20AQ. On the other hand, when the control signal is not input to the first driver 234A, the first driver 234A does not supply the current to the second light emitting diode 20AQ.

The second control circuit 230B includes a second Schmitt trigger 231B, a second output unit 232B, a second current source 233B, and a second driver 234B. The second current source 233B and the second driver 234B form a drive unit that drives the first light emitting diode 20AP. The second control circuit 230B generates a drive voltage signal based on a change in the voltage of the second light receiving diode 30AQ caused when the second light receiving diode 30AQ receives light from the second light emitting diode 20AQ.

The second Schmitt trigger 231B is electrically connected to both the first electrode 31Q and the second electrode 32Q of the second light receiving diode 30AQ. The second Schmitt trigger 231B is electrically connected to the terminals 51A and 51D. That is, power is supplied from the control power supply 503 to the second Schmitt trigger 231B. The second Schmitt trigger 231B transmits the voltage of the second light receiving diode 30AQ to the second output unit 232B. A predetermined hysteresis is given to a threshold voltage of the second Schmitt trigger 231B. This configuration enhances the resistance to noise.

The second output unit 232B has a first switching element 232Ba and a second switching element 232Bb connected in series with each other. In the example illustrated in FIG. 11, a p-type MOSFET is used as the first switching element 232Ba, and an n-type MOSFET is used as the second switching element 232Bb. Since the electrical connection manner of the first switching element 232Ba and the second switching element 232Bb is similar to the electrical connection manner of the first switching element 232Aa and the second switching element 232Ab, the detailed description thereof will be omitted.

The second current source 233B is electrically connected between the terminal 51A and the first electrode 21P of the first light emitting diode 20AP. As a result, a constant current is supplied from the terminal 51A to the first light emitting diode 20AP.

The second driver 234B is electrically connected to both the second current source 233B and the terminal 51B. The second driver 234B is a circuit that controls the supply of the current to the first light emitting diode 20AP. That is, the second driver 234B controls the supply of the current to the first light emitting diode 20AP based on the control signal supplied to the terminal 51B from the outside of the insulation module 10. In one example, when the control signal is input to the second driver 234B, the second driver 234B supplies a current to the first light emitting diode 20AP. On the other hand, when the control signal is not input to the second driver 234B, the second driver 234B does not supply the current to the first light emitting diode 20AP.

In the present embodiment, a detection circuit 505 that detects a voltage between the source of the first switching element 501 and the drain of the second switching element 502 of the inverter circuit 500 is electrically connected to the terminal 51B. When detecting that the voltage between the source of the first switching element 501 and the drain of the second switching element 502 is excessively high, the detection circuit 505 supplies an anomaly signal to the terminal 51B as a control signal. In one example, the detection circuit 505 is configured to supply the anomaly signal to the terminal 51B when the voltage between the source of the first switching element 501 and the drain of the second switching element 502 becomes greater than a preset threshold.

In the insulation module 10 of the present embodiment, the first control circuit 230A may have a current limiting resistor instead of the first current source 233A. The second control circuit 230B may have a current limiting resistor instead of the second current source 233B.

In addition, the first driver 234A and the first current source 233A may be omitted from the first control circuit 230A. In this case, the first electrode 21Q of the second light emitting diode 20AQ is electrically connected to the terminal 41A, and the second electrode 22Q is electrically connected to the terminal 41D. The second driver 234B and the second current source 233B may be omitted from the second control circuit 230B. In this case, the first electrode 21P of the first light emitting diode 20AP is electrically connected to the terminal 51A, and the second electrode 22P is electrically connected to the terminal 51D.

Operation

Operation of the insulation module 10 of the present embodiment will be described.

In order to enhance the insulation properties of the terminals 41A to 41D and the terminals 51A to 51D, it is necessary to increase a creepage distance between adjacent terminals among the terminals 41A to 41D and a creepage distance between adjacent terminals among the of terminals 51A to 51D.

As a structure for increasing the creepage distance, it is conceivable to increase the distance between adjacent terminals among the terminals 41A to 41D in the y-direction and a distance between adjacent terminals among the terminals 51A to 51D in the y-direction. However, if these distances are increased, the insulation module 10 becomes large.

In this regard, in the present embodiment, the uneven portion 87 is provided between the terminals adjacent to each other among the terminals 41A to 41D, and the uneven portion 88 is provided between the terminals adjacent to each other among the terminals 51A to 51D. In this case, for example, the creepage distance between the terminal 41C and the terminal 41D increases by the distance of the inner surfaces of the recessed sections 87a of the uneven portion 87. Therefore, it is possible to increase the creepage distance while suppressing an increase in size of the insulation module 10.

Advantages

According to the insulation module 10 of the present embodiment, the following advantages are obtained.
(1) The insulation module 10 includes the first light emitting element 20P and the first light receiving element 30P forming a photocoupler, the first plate-shaped member 70P having translucency and provided between the first light receiving element 30P and the first light emitting element 20P, and the sealing plastic 80, which seals at least the first light emitting element 20P and the first light receiving element 30P, and has the terminals 41A to 41D and 51A to 51D provided side by side. The first plate-shaped member 70P is stacked on the light receiving surface 33P of the first light receiving element 30P, and the first light emitting element 20P is stacked on the first plate-shaped member 70P. The uneven portion 87 is provided in a portion between adjacent terminals among the terminals 41A to 41D on the first plastic side surface 81. The uneven portion 88 is provided in a portion between adjacent terminals among the terminals 51A to 51D on the second plastic side surface 82.

This configuration increases the creepage distance of the portion between the adjacent terminals among the terminals 41A to 41D on the plastic side surface 81. In addition, it is possible to increase the creepage distance of a portion between adjacent terminals among the terminals 51A to 41D on the plastic side surface 82. Therefore, it is possible to enhance insulation between adjacent terminals among the terminals 41A to 41D, and it is possible to enhance insulation between adjacent terminals among the terminals 51A to 51D.

In the present embodiment, the suspension lead 46D provided on the die pad portion 42DB is exposed from the portion of the first plastic side surface 81 between the terminal 41A and the terminal 41B. Therefore, the terminal 41A and the suspension lead 46D are adjacent to each other, and the suspension lead 46D and the terminal 41B are adjacent to each other between the terminal 41A and the terminal 41B. The uneven portion 87 is provided between the terminal 41A and the suspension lead 46D on the first plastic side surface 81, and the uneven portion 87 is provided between the suspension lead 46D and the terminal 41B. As a result, both the creepage distance between the terminal 41A and the suspension lead 46D and the creepage distance between the suspension lead 46D and the terminal 41B on the first plastic side surface 81 are increased, so that the insulation properties between the terminal 41A and the suspension lead 46D and the insulation properties between the suspension lead 46D and the terminal 41B are both improved.
(2) The insulation module 10 includes the insulation bonding material 90P bonded to the first light emitting element 20P and the first plate-shaped member 70P. The insulation bonding material 90P bonds the side surface of the first light emitting element 20P and the first plate-shaped member 70P. That is, the insulation bonding material 90P is not interposed between the element back surface 20Pr of the first light emitting element 20P and the main surface 70Ps of the first plate-shaped member 70P.

According to this configuration, the insulation bonding material 90P is not provided between the first light emitting element 20P and the first light receiving element 30P in the z-direction, that is, in the middle of the optical path in which the light from the first light emitting element 20P is emitted to the light receiving surface 33P of the first light receiving element 30P. This prevents the light from the first light emitting element 20P from being blocked by the insulation bonding material 90P. Therefore, the reduction in the amount of received light of the first light receiving element 30P is limited.
(3) The first light emitting element 20P has an element back surface 20Pr as a light emitting surface facing the light receiving surface 33P of the first light receiving element 30P. The element back surface 20Pr is in contact with the first plate-shaped member 70P.

According to this configuration, since a gap is unlikely to be formed between the element back surface 20Pr of the first light emitting element 20P and the main surface 70Ps of the first plate-shaped member 70P, light from the first light emitting element 20P is prevented from leaking through the gap. This limits the reduction in the amount of received light of the first light receiving element 30P.
(4) The insulation bonding material 90P is formed of a plastic material that absorbs light.

According to this configuration, the light other than the light from the first light emitting element 20P is prevented from entering the light receiving surface 33P of the first light receiving element 30P by the insulation bonding material 90P.
(5) The transparent plastic 60P, which bonds the first light receiving element 30P and the first plate-shaped member 70P to each other, is provided between the light receiving surface 33P of the first light receiving element 30P and the first plate-shaped member 70P.

This configuration achieves both bonding of the first light receiving element 30P and the first plate-shaped member 70P and incident light from the first light emitting element 20P on the light receiving surface 33P of the first light receiving element 30P via the first plate-shaped member 70P.
(6) The light transmittance of the first plate-shaped member 70P is lower than the light transmittance of the first transparent plastic 60P.

According to this configuration, the amount of light incident on the light receiving surface 33P of the first light receiving element 30P is reduced by the light from the first light emitting element 20P passing through the first plate-shaped member 70P. This reduces the amount of light received by the first light receiving element 30P. That is, when the amount of received light of the first light receiving element 30P is greater than a predetermined range set in advance, the amount of received light of the first light receiving element 30P can be adjusted to fall within a predetermined range by setting the light transmittance of the first plate-shaped member 70P to be low.
(7) The first plate-shaped member 70P has a portion protruding from the first light receiving element 30P when viewed from the z-direction.

This configuration increases the creepage distance between the first light emitting element 20P and the first light receiving element 30P. This enhances the insulation properties between the first light emitting element 20P and the first light receiving element 30P.
(8) The insulation module 10 includes the die pad portion 42DB, on which the first light receiving element 30P is mounted, and the conductive bonding material 100P, which bonds the die pad portion 42DB and the first light receiving element 30P to each other. The conductive bonding material 100P includes the first bonding region 101P interposed between the element back surface 30Pr of the first light receiving element 30P and the die pad portion 42DB, and the second bonding region 102P protruding from the first light receiving element 30P when viewed from the z-direction. The portion of the second bonding region 102P in contact with the side surface of the first light receiving element 30P is formed to be closer to the light receiving surface 33P than the center of the first light receiving element 30P in the z-direction.

According to this configuration, since the bonding area between the side surface of the first light receiving element 30P and the conductive bonding material 100P is increased, the bonding force between the first light receiving element 30P and the die pad portion 42DB is increased.
(9) The substrate 23P of the first light emitting element 20P is a sapphire substrate.

This configuration enhances the insulation of the first light emitting element 20P as compared with a case where the substrate 23P is, for example, a Si substrate.
(10) The die pad portion 42DB, on which the first light receiving element 30P is mounted, is disposed closer to the plastic back surface 80r than the position where the terminal 41D is exposed from the plastic side surface 81 in the z-direction.

According to this configuration, the stacked body of the first light receiving element 30P, the first transparent plastic 60P, the first plate-shaped member 70P, and the first light emitting element 20P is prevented from being disposed to be shifted toward the plastic main surface 80s with respect to the position where the terminal 41D is exposed from the plastic side surface 81 in the z-direction. As a result, the distance between the position where the terminal 41D is exposed from the plastic side surface 81 and the plastic main surface 80s in the z-direction is reduced, so that the height of the insulation module 10 is reduced.
(11) The thickness of the first light emitting element 20P is less than the thickness of the first light receiving element 30P.

According to this configuration, as compared with the case where the thickness of the first light emitting element 20P is greater than or equal to the thickness of the first light receiving element 30P, the total thickness of the first light emitting element 20P and the first light receiving element 30P is reduced in a case where the first light emitting element 20P and the first light receiving element 30P are stacked. This reduces the height of the insulation module 10.
(12) The insulation module 10 includes the first photocoupler including the first light emitting element 20P and the first light receiving element 30P, and the second photocoupler including the second light emitting element 20Q and the second light receiving element 30Q. The first light emitting element 20P is electrically connected to the first lead frame 40, and the second light emitting element 20Q is electrically connected to the second lead frame 50. The first light receiving element 30P is electrically connected to the second lead frame 50, and the second light receiving element 30Q is electrically connected to the first lead frame 40.

According to this configuration, the first photocoupler transmits a signal from the first lead frame 40 to the second lead frame 50, and the second photocoupler transmits a signal from the second lead frame 50 to the first lead frame 40. In this way, the insulation module 10 can transmit signals bidirectionally.

Modification

The above embodiment is an example of a possible configuration of the insulation module according to the present disclosure, and is not intended to limit the configuration. The insulation module according to the present disclosure can take a configuration different from the configuration exemplified in the above embodiment. An example thereof is a configuration in which a part of the configuration of the above embodiment is replaced, changed, or omitted, or a configuration in which a new configuration is added to the above embodiment. In addition, the following modifications can be combined with each other as long as they are not technically inconsistent. In the following modification examples, the same reference numerals as those of the above embodiments are given to portions common to the above embodiments, and the description thereof will be omitted.

In the above embodiment, the uneven portions 87 and 88 may be omitted from the sealing plastic 80.

In the above embodiment, the configuration of the insulation bonding material 90Q, which bonds the second light emitting element 20Q and the second plate-shaped member 70Q to each other, can be changed. In one example, the insulation bonding material 90Q may be formed of a material having translucency. In this case, the insulation bonding material 90Q may be interposed between the element back surface 20Qr of the second light emitting element 20Q and the main surface 70Qs of the second plate-shaped member 70Q. As a result, the light from the second light emitting element 20Q is incident on the light receiving surface 33Q of the second light receiving element 30Q via the insulation bonding material 90Q and the second plate-shaped member 70Q. The insulation bonding material 90P can be similarly changed.

In the above embodiment, the bonding material for bonding the second light emitting element 20Q and the second plate-shaped member 70Q to each other is not limited to the insulation bonding material, and may be a conductive bonding material. Similarly, the bonding material for bonding the first light emitting element 20P and the first plate-shaped member 70P to each other may be a conductive bonding material.

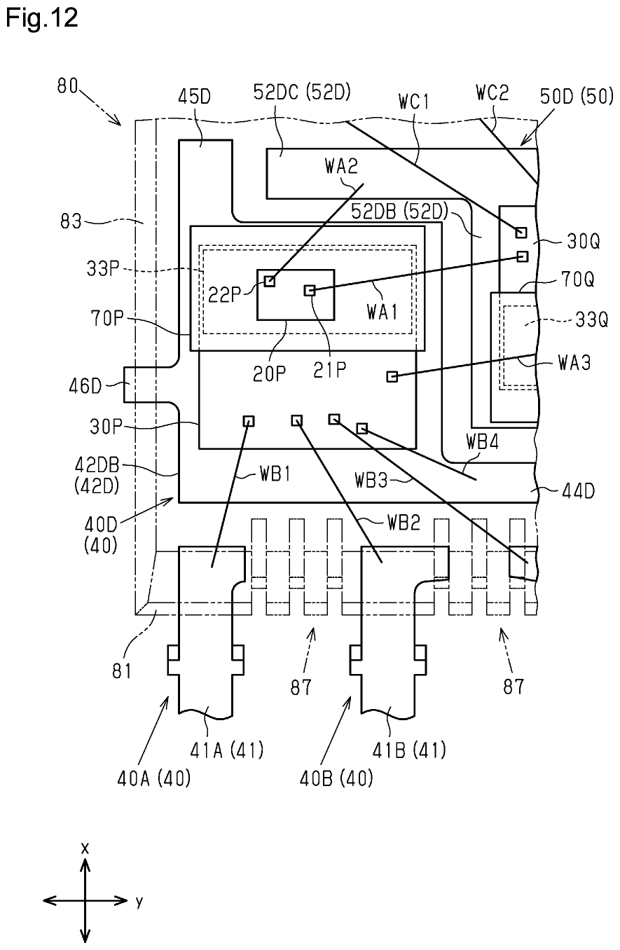

In the above embodiment, the position of the suspension lead 46D provided on the die pad portion 42DB of the first lead frame 40D can be changed. In one example, as illustrated in FIG. 12, the suspension lead 46D may be provided at the end closer to the third plastic side surface 83 of the opposite ends of the die pad portion 42DB in the y-direction. In this case, the suspension lead 46D extends in the y-direction toward the third plastic side surface 83 and is exposed from the third plastic side surface 83. That is, the suspension lead 46D is not exposed from the portion between the terminal 41A and the terminal 41B on the first plastic side surface 81. In the modification shown in FIG. 12, the first plastic side surface 81 and the second plastic side surface 82 correspond to a “terminal surface”, and the third plastic side surface 83 corresponds to a “suspension lead surface”.

According to this configuration, since the suspension lead 46D is not exposed from a portion between the terminal 41A and the terminal 41B in the y-direction on the first plastic side surface 81, the creepage distance that affects the insulation properties is a portion between the terminal 41A and the terminal 41B on the first plastic side surface 81. In addition, since the number of recessed sections and projections of the uneven portion 87 between the terminal 41A and the terminal 41B is increased, the creepage distance between the terminal 41A and the terminal 41B is increased. Therefore, insulation properties between the terminal 41A and the terminal 41B is enhanced.

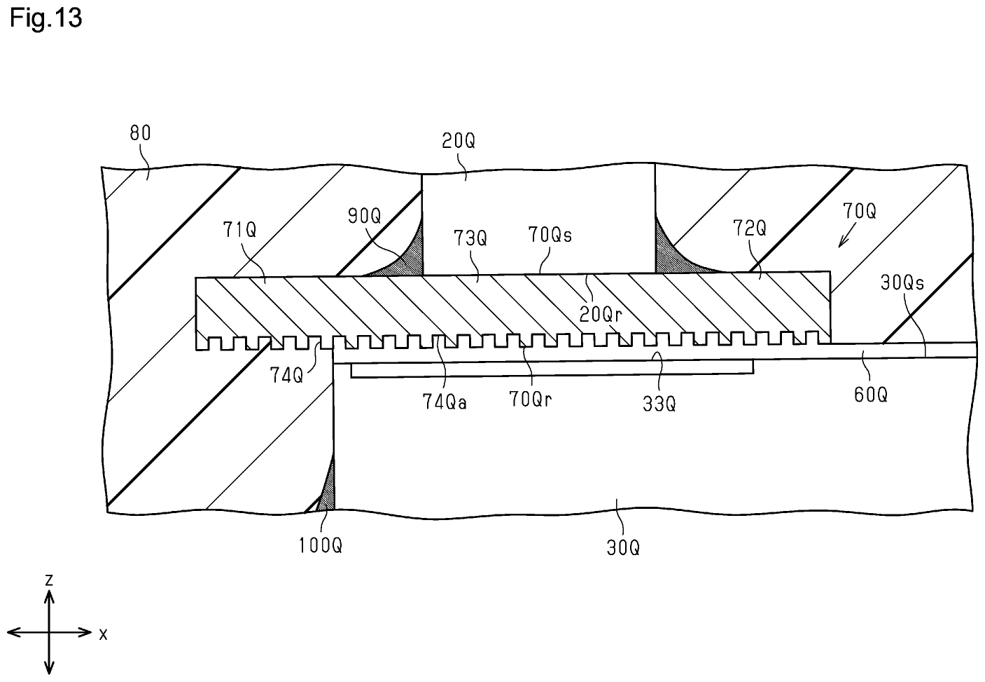

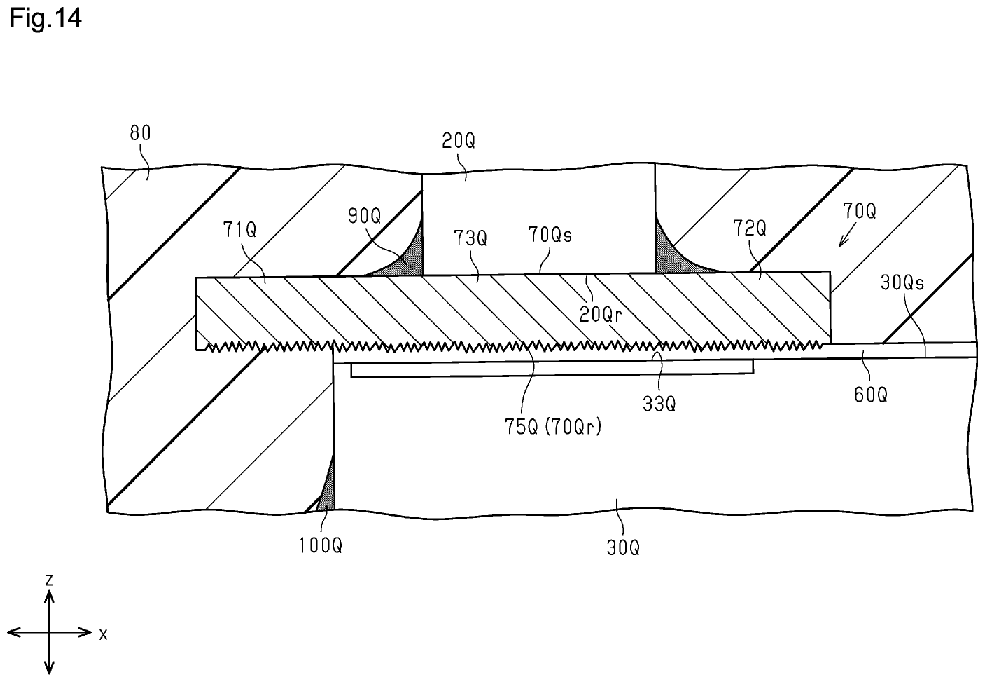

In the above embodiment, the configuration of the second plate-shaped member 70Q can be changed. For example, FIG. 13 illustrates a configuration of a first modification of the second plate-shaped member 70Q, and FIG. 14 illustrates a configuration of a second modification of the second plate-shaped member 70Q. FIGS. 13 and 14 show cross-sectional views of the second plate-shaped member 70Q and its periphery. The first plate-shaped member 70P can be similarly changed.

As illustrated in FIG. 13, in the second plate-shaped member 70Q of the first modification, the uneven portion 74Q may be provided on the back surface 70Qr of the second plate-shaped member 70Q. The uneven portion 74Q may be provided over the entire back surface 70Qr of the second plate-shaped member 70Q. Recessed sections 74Qa in the uneven portion 74Q, which is in contact with the second transparent plastic 60Q, are filled with the second transparent plastic 60Q. The main surface 70Qs of the second plate-shaped member 70Q is a flat surface formed to have a flat shape. In the modification shown in FIG. 13, the uneven portion 74Q corresponds to the “second uneven portion”.

According to this configuration, since the creepage distance between the second plate-shaped member 70Q and the second transparent plastic 60Q is increased, the insulation properties between the second light emitting element 20Q and the second light receiving element 30Q is enhanced. In addition, since the main surface 70Qs of the second plate-shaped member 70Q is a flat surface, it is possible to suppress formation of a gap between the second light emitting element 20Q and the main surface 70Qs of the second plate-shaped member 70Q, and thus, it is possible to suppress entry of the insulation bonding material 90Q into the gap. The first plate-shaped member 70P can be similarly changed.

As shown in FIG. 14, in the second plate-shaped member 70Q of the second modification, the back surface 70Qr of the second plate-shaped member 70Q may have a rough surface 75Q, which scatters light from the second light emitting element 20Q. The rough surface 75Q may be formed over the entire back surface 70Qr of the second plate-shaped member 70Q. The second transparent plastic 60Q is in contact with the rough surface 75Q, which is in contact with the second transparent plastic 60Q. The main surface 70Qs of the second plate-shaped member 70Q is a flat surface formed to have a flat shape.

According to this configuration, the light from the second light emitting element 20Q is scattered by the rough surface 75Q when passing through the second plate-shaped member 70Q. As a result, the light is incident on the light receiving surface 33Q of the second light receiving element 30Q in a weakened state. This reduces the amount of received light of the second light receiving element 30Q. That is, when the light reception amount of the second light receiving element 30Q is greater than a predetermined range, the light reception amount of the second light receiving element 30Q can be adjusted to fall within the predetermined range by using the configuration of the second plate-shaped member 70Q of the second modification.

The rough surface 75Q may be provided on the main surface 70Qs instead of the back surface 70Qr. The rough surface 75Q may be provided on the main surface 70Qs in addition to the back surface 70Qr. The rough surface 75Q may be formed over the entire outer surface of the second plate-shaped member 70Q.

In the above embodiment, at least one of the second plate-shaped member 70Q and the second transparent plastic 60Q may contain inorganic particles that absorb or reflect light from the second light emitting element 20Q. That is, the second plate-shaped member 70Q may contain inorganic particles, while the second transparent plastic 60Q does not contain inorganic particles. The second transparent plastic 60Q may contain inorganic particles, while the second plate-shaped member 70Q does not contain inorganic particles. In addition, both the second plate-shaped member 70Q and the second transparent plastic 60Q may contain inorganic particles.

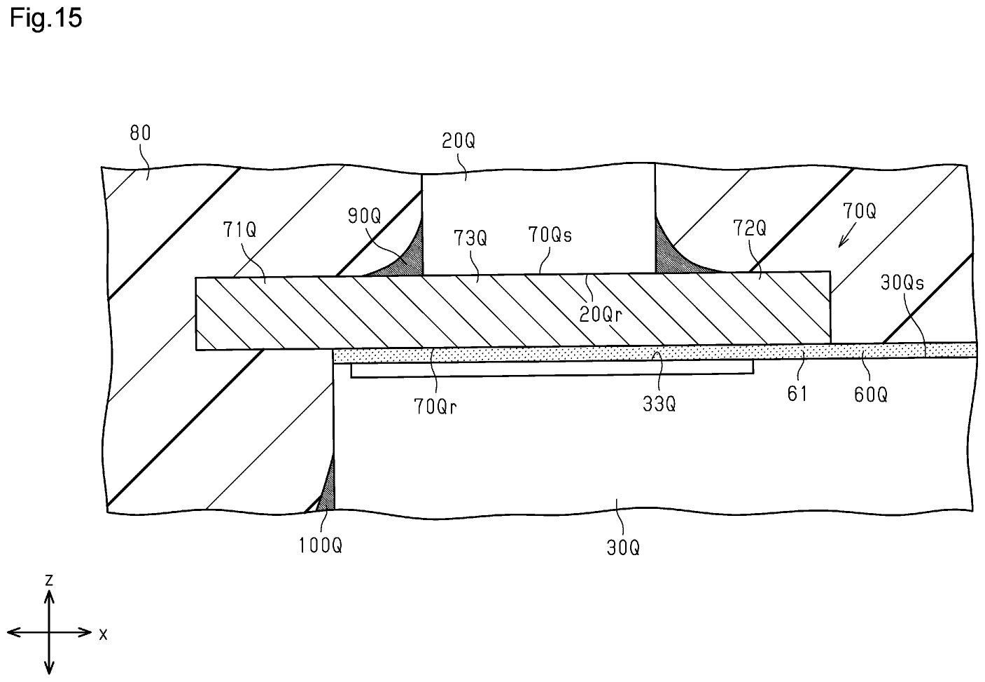

In one example, as shown in FIG. 15, the second transparent plastic 60Q contains inorganic particles 61. On the other hand, the second plate-shaped member 70Q does not contain inorganic particles. An example of the inorganic particles 61 is a filler. The inorganic particles 61 are disposed over the entire second transparent plastic 60Q.

The content of the inorganic particles 61 in the second transparent plastic 60Q can be changed. The content of the inorganic particles 61 in the second transparent plastic 60Q is set, for example, such that the second light receiving element 30Q can receive light from the second light emitting element 20Q with a light amount within a predetermined range.

The cross-sectional shape of the inorganic particles 61 may be elliptical or circular. The inorganic particles 61 may include multiple types of inorganic particles having different cross-sectional shapes. In one example, the inorganic particle 61 may include a first inorganic particle having a first cross-sectional shape and a second inorganic particle having a second cross-sectional shape different from the first cross-sectional shape.

The inorganic particles 61 may have the same size as each other. In addition, the inorganic particles 61 may include multiple types of inorganic particles having different sizes. In one example, the inorganic particles 61 may include a first inorganic particle having a first size and a second inorganic particle having a second size different from the first size.

The inorganic particles 61 may include multiple types of inorganic particles made of materials different from each other. In one example, the inorganic particles 61 may include a first inorganic particle formed of a first material and a second inorganic particle formed of a second material different from the first material.

The inorganic particles 61 are composed of inorganic particles having the same size, the same cross-sectional shape, and the same material.

The inorganic particles 61 may include multiple types of inorganic particles formed of a combination of multiple types of cross-sectional shapes, multiple types of sizes, and multiple types of materials. The color of the inorganic particles 61 may be black, which mainly absorbs light, or may be white, which mainly reflects light. Similarly, at least one of the first transparent plastic 60P and the first plate-shaped member 70P may contain inorganic particles that absorb or reflect light from the first light emitting element 20P.

When the inorganic particles 61 are contained in at least one of the second transparent plastic 60Q and the second plate-shaped member 70Q, the die pad portion 52DB, on which the second light receiving element 30Q is mounted, may be configured to be inclined toward the plastic back surface 80r from the second plastic side surface 82 toward the first plastic side surface 81.

An inclination angle of the die pad portion 52DB with respect to a direction perpendicular to the z-direction (horizontal direction) is, for example, in a range of 1° to 2°. The inclination angle of the die pad portion 52DB with respect to the horizontal direction is not limited thereto, and may be, for example, greater than 0° and 10° or less. The inclination angle of the die pad portion 52DB with respect to the horizontal direction may be in any of a range of 2° to 3°, a range of 3° to 4°, a range of 4° to 5°, a range of 5° to 6°, a range of 6° to 7°, and a range of 7° to 8°.

As described above, by providing the die pad portion 52DB to be inclined with respect to the horizontal direction, the height positions of the terminals 51A to 51D protruding from the second plastic side surface 82 of the sealing plastic 80 can be aligned with the height position of the standard defined in advance, and the thick inorganic particles 61 can be included in at least one of the second transparent plastic 60Q and the second plate-shaped member 70Q. That is, by including the inorganic particles 61 in at least one of the second transparent plastic 60Q and the second plate-shaped member 70Q, even if the volume of the member in which the inorganic particles 61 are included increases, the die pad portion 52DB is inclined with respect to the horizontal direction, so that a space for the increase in the volume is secured.

When at least one of the first transparent plastic 60P and the first plate-shaped member 70P contains inorganic particles, the die pad portion 42DB, on which the first light receiving element 30P is mounted, may be configured to be inclined toward the plastic back surface 80r from the first plastic side surface 81 toward the second plastic side surface 82. That is, the inclination direction of the die pad portion 42DB with respect to the horizontal direction is opposite to the inclination direction of the die pad portion 52DB, on which the second light receiving element 30Q is mounted, with respect to the horizontal direction. The inclination angle of the die pad portion 42DB with respect to the horizontal direction is similar to the inclination angle of the die pad portion 52DB with respect to the horizontal direction.

As described above, by providing the die pad portion 42DB to be inclined with respect to the horizontal direction, the height positions of the terminals 41A to 41D protruding from the first plastic side surface 81 of the sealing plastic 80 can be aligned with the height position of the standard defined in advance, and the thick inorganic particles can be included in at least one of the first transparent plastic 60P and the first plate-shaped member 70P. That is, by including the inorganic particles in at least one of the first transparent plastic 60P and the first plate-shaped member 70P, even if the volume of the member in which the inorganic particles are included increases, the die pad portion 42DB is inclined with respect to the horizontal direction, so that a space for the increase in the volume is secured.

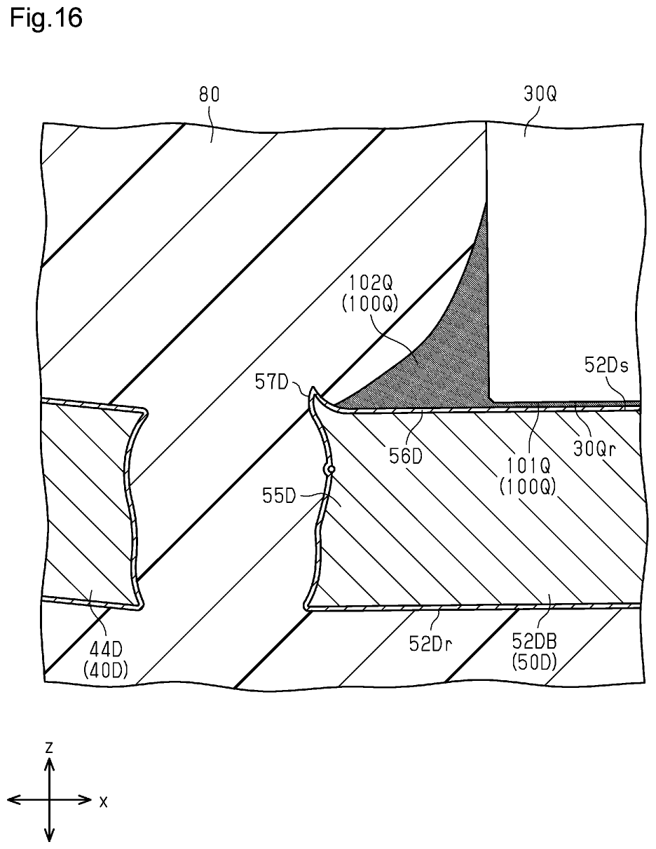

In the above embodiment, as shown in FIG. 16, a protrusion 57D may be provided at the end closer to the second plastic side surface 82 (see FIG. 3) of the opposite ends of the die pad portion 52DB of the second lead frame 50D in the x-direction. The protrusion 57D extends upward. More specifically, the protrusion 57D includes a main metal layer 55D and a plating layer 56D. The height dimension of a portion of the protrusion 57D formed by the main metal layer 55D is greater than the thickness of the plating layer 56D. The height dimension of the protrusion 57D can be changed within a range in which an effect of suppressing leakage of the conductive bonding material 100Q to the side surface of the die pad portion 52DB in the x-direction is obtained.

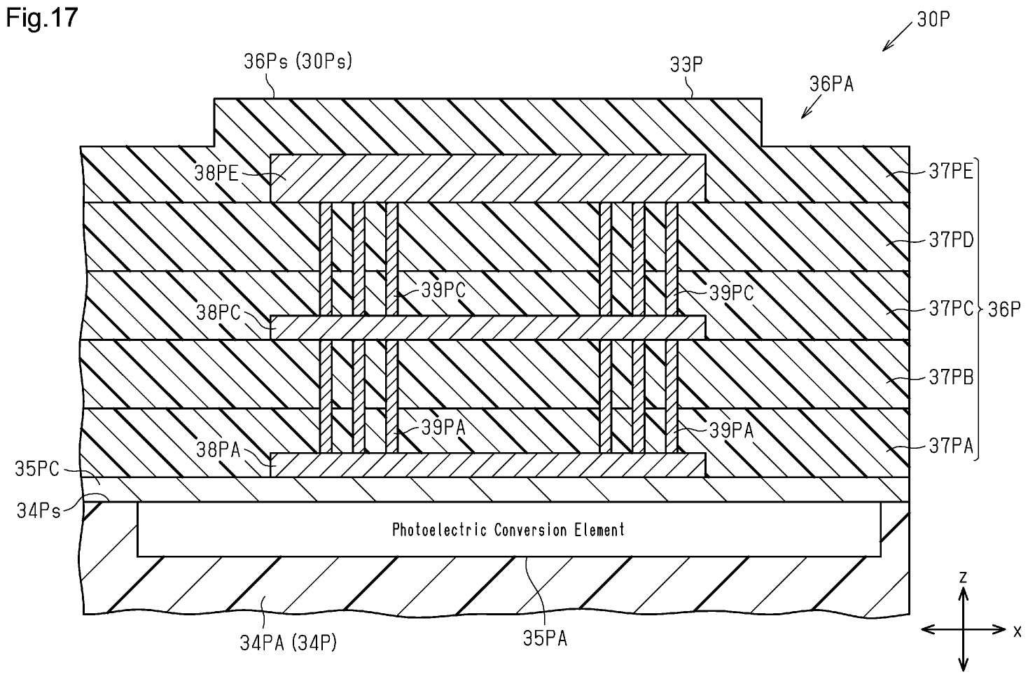

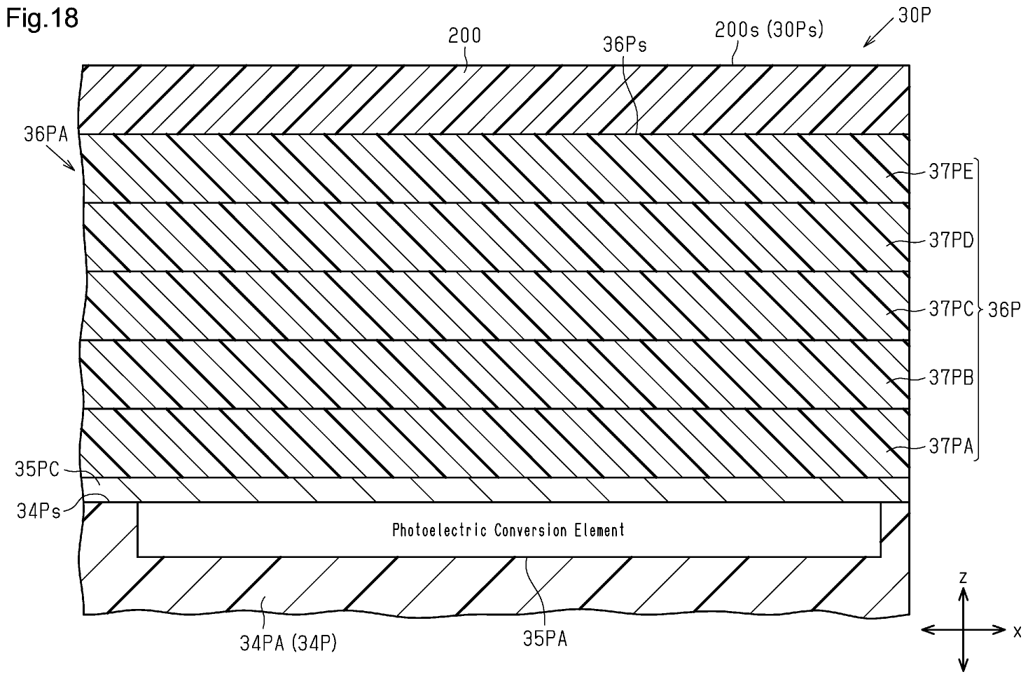

In the above embodiment, the configurations of the first light receiving element 30P and the second light receiving element 30Q can be changed. For example, FIG. 17 illustrates a configuration of a first modification of the first light receiving element 30P, and FIG. 18 illustrates a configuration of a second modification of the first light receiving element 30P. FIGS. 17 and 18 illustrate a cross-sectional structure close to element main surface 30Ps of first light receiving element 30P. In FIGS. 17 and 18, the cross-sectional structure of the photoelectric conversion element 35PA and its periphery in the element main surface 30Ps of the first light receiving element 30P is enlarged. The cross-sectional structure of the control circuit 35PB and its periphery in the element main surface 30Ps of the first light receiving element 30P is similar to that of the above embodiment (see FIG. 8). In the following description, the first light receiving element 30P having a configuration different from that of the above embodiment will be described in detail. Since the configuration of the second light receiving element 30Q can be changed similarly to the configuration of the first light receiving element 30P, the detailed description thereof will be omitted.

As illustrated in FIG. 17, in the first light receiving element 30P of the first modification, a wiring layer is also provided in the first insulation portion 36PA corresponding to the first semiconductor region 34PA in the insulation layer 36P. On the other hand, the number of layers of the wiring layers provided in the first insulation portion 36PA is different from the number of layers of the wiring layers 38PA to 38PE of the second insulation portion 36PB. More specifically, in the first insulation portion 36PA and the second insulation portion 36PB, the number of stacked layers of the insulation films (insulation films 37PA to 37PE) is equal to each other. On the other hand, the number of layers of the wiring layers of the first insulation portion 36PA is smaller than the number of layers of the second insulation portion 36PB (wiring layers 38PA to 38PE). That is, the first insulation portion 36PA has at least one insulation film on which no wiring layer is formed. In the first modification, the first insulation portion 36PA does not include the wiring layers 38PB and 38PD. Therefore, in the first insulation portion 36PA, the insulation films 37PB and 37PD are insulation films on which no wiring layer is formed. In the first modification, the wiring layers 38PA, 38PC, and 38PE of the first insulation portion 36PA correspond to the “second wiring layer”, and the wiring layers 38PA to 38PE of the second insulation portion 36PB correspond to the “first wiring layer”.

As described above, in the first light receiving element 30P of the first modification, at least one first wiring layer is formed in the second insulation portion 36PB, and at least one layer on which no wiring layer is formed is provided in the first insulation portion 36PA. Further, in the first light receiving element 30P of the first modification, multiple first wiring layers are formed in the second insulation portion 36PB, and a smaller number of second wiring layers than the second insulation portion 36PB are formed in the first insulation portion 36PA.

The wiring layers 38PA, 38PC, and 38PE in the first insulation portion 36PA are provided at positions overlapping the photoelectric conversion element 35PA when viewed from the z-direction. In the first modification, the photoelectric conversion element 35PA has a region protruding from the wiring layers 38PA, 38PC, and 38PE when viewed from the z-direction. The insulation films 37PA to 37PE are provided on regions of the photoelectric conversion element 35PA protruding from the wiring layers 38PA, 38PC, and 38PE.

When viewed from the z-direction, the amount of received light of the photoelectric conversion element 35PA may be adjusted by adjusting the area (hereinafter, it is simply referred to as an area of each of the wiring layers 38PA, 38PC, and 38PE) of each layer of the wiring layers 38PA, 38PC, and 38PE provided on the photoelectric conversion element 35PA. That is, at the time of designing the insulation module 10, the areas of the wiring layers 38PA, 38PC, and 38PE are set so that the light reception amount of the photoelectric conversion element 35PA falls within a preset range. In one example, the area of each of the wiring layers 38PA, 38PC, and 38PE is set such that the ratio of light that enters the photoelectric conversion element 35PA in the vertical direction without being reflected is in a range of 60% to 70% in the z-direction. The ratio of light entering the photoelectric conversion element 35PA in the vertical direction without being reflected is not limited to the range of 60% to 70%, and may be, for example, a range of 30% to 40%, a range of 40% to 50%, a range of 50% to 60%, a range of 70% to 80%, a range of 80% to 90%, or the like. As described above, the ratio of light entering the photoelectric conversion element 35PA in the vertical direction without being reflected is appropriately adjusted by adjusting the wiring pattern of each of the wiring layers 38PA, 38PC, and 38PE in accordance with the characteristics and the like of the photoelectric conversion element 35PA.

According to this configuration, since the number of wiring layers electrically connected to the control circuit 35PB is smaller in the first insulation portion 36PA, on which the light from the first light emitting element 20P is incident, than in the second insulation portion 36PB, it is possible to eliminate the malfunction of the control circuit 35PB caused by inrush light or the like when the amount of light from the first light emitting element 20P is large. In addition, by adjusting the area of each of the wiring layers 38PA, 38PC, and 38PE, it is possible to adjust the ratio of light incident in the vertical direction without being reflected on the photoelectric conversion element 35PA in accordance with the characteristics of the photoelectric conversion element 35PA.

As illustrated in FIG. 18, in the first light receiving element 30P of the second modification, a plastic layer 200 is provided on the insulation layer 36P. That is, the plastic layer 200 is formed on the front surface 36Ps of the insulation layer 36P. In the second modification, the plastic layer 200 is formed over the entire front surface 36Ps of the insulation layer 36P. That is, a surface 200s of the plastic layer 200 forms the element main surface 30Ps of the first light receiving element 30P.

The plastic layer 200 has insulation properties and is formed of a plastic material that selectively absorbs or blocks infrared rays. In the second modification, the plastic layer 200 corresponds to an “infrared ray cut layer”. The plastic layer 200 is formed, for example, by being applied to the front surface 36Ps of the insulation layer 36P. The plastic layer 200 may be formed of, for example, a plastic material having a lower light transmittance than the first transparent plastic 60P. The plastic layer 200 may be formed of, for example, a material having a lower light transmittance than the first plate-shaped member 70P. Furthermore, the insulation layer 36P may be formed of a material that transmits infrared rays. The material of the insulation layer 36P is not limited thereto and may be any material.

The formation range of the plastic layer 200 on the front surface 36Ps of the insulation layer 36P can be changed. In one example, plastic layer 200 may be formed only in a region of front surface 36Ps of insulation layer 36P corresponding to first insulation portion 36PA.

The thickness of the plastic layer 200 can be changed. In one example, the thickness of the plastic layer 200 may be greater than the thickness of the insulation layer 36P. In another example, the thickness of the plastic layer 200 may be less than the thickness of the insulation layer 36P.

According to this configuration, since the plastic layer 200 absorbs or blocks infrared rays, light from the first light emitting element 20P is supplied to the first light receiving element 30P in a state of being weakened by the plastic layer 200. This reduces the amount of received light of the first light receiving element 30P from the first light emitting element 20P. Since the second light receiving element 30Q has the same configuration as the first light receiving element 30P, the above-described advantages are achieved.

In the above embodiment, the wiring layers 38PA to 38PE may be provided in the first insulation portion 36PA. In this case, the photoelectric conversion element 35PA has a region protruding from the wiring layers 38PA to 38PE when viewed from the z-direction.

When viewed from the z-direction, the amount of received light of the photoelectric conversion element 35PA may be adjusted by adjusting the area (hereinafter, it is simply referred to as an area of each of the wiring layers 38PA to 38PE) of each layer of the wiring layers 38PA to 38PE provided on the photoelectric conversion element 35PA. That is, at the time of designing the insulation module 10, the areas of the wiring layers 38PA to 38PE are set such that the light reception amount of the photoelectric conversion element 35PA falls within a preset range. In one example, the area of each of the wiring layers 38PA to 38PE is set such that the ratio of light that enters the photoelectric conversion element 35PA in the vertical direction without being reflected is in a range of 60% to 70% in the z-direction. The ratio of light entering the photoelectric conversion element 35PA in the vertical direction without being reflected is not limited the range of 60% to 70%, and may be, for example, a range of 30% to 40%, a range of 40% to 50%, a range of 50% to 60%, a range of 70% to 80%, a range of 80% to 90%, or the like. As described above, the ratio of light entering the photoelectric conversion element 35PA in the vertical direction without being reflected is appropriately adjusted by adjusting the wiring pattern of each of the wiring layers 38PA to 38PE in accordance with the characteristics and the like of the photoelectric conversion element 35PA and the like.

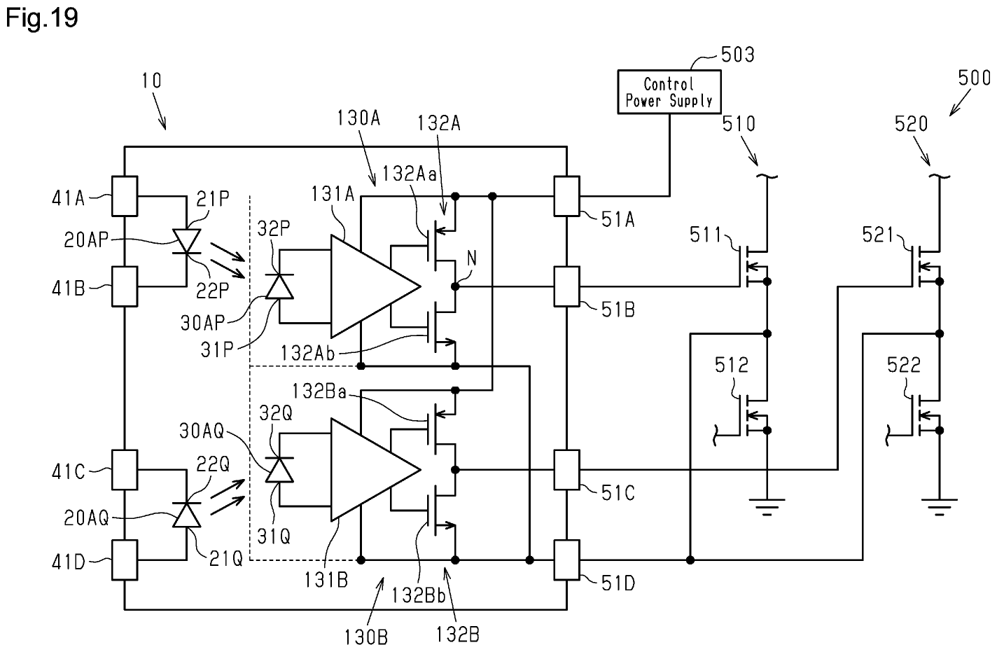

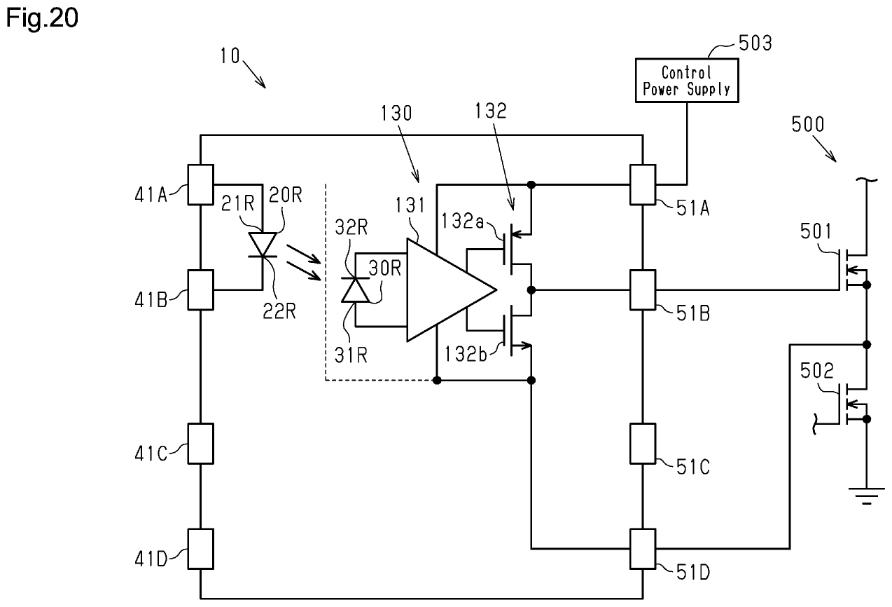

In the above embodiment, the circuit configuration of the insulation module 10 and the connection configuration between the insulation module 10 and the inverter circuit 500 can be changed. For example, FIG. 19 illustrates the circuit configuration of the first modification of the insulation module 10, and FIG. 20 illustrates the circuit configuration of the second modification of the insulation module 10. FIGS. 19 and 20 are circuit diagrams schematically illustrating the circuit configuration of the insulation module 10 and the connection configuration between the insulation module 10 and the inverter circuit 500.

The inverter circuit 500, to which the insulation module 10 of the first modification of FIG. 19 is connected, is a full-bridge type inverter circuit and includes a first inverter circuit 510 and a second inverter circuit 520 connected in parallel with the first inverter circuit 510. The first inverter circuit 510 includes a first switching element 511 and a second switching element 512 connected in series with each other. The second inverter circuit 520 includes a first switching element 521 and a second switching element 522 connected in series with each other. Each switching element 511, 512, 521, and 522 is, for example, a power transistor. That is, the insulation module 10 of the first modification is an insulation type gate driver used for a power transistor. In the first modification, a MOSFET is used for each switching element 511, 512, 521, and 522.

In the first modification, the insulation module 10 applies a drive voltage signal to each of the gate of the first switching element 511 and the gate of the first switching element 521. That is, the insulation module 10 is a gate driver that drives the first switching element 511 and 521.

A positive electrode of a control power supply 503 is electrically connected to the terminal 51A of the insulation module 10. The terminal 51D of the insulation module 10 is electrically connected to both the source of the first switching element 511 of the first inverter circuit 510 and the source of the first switching element 521 of the second inverter circuit 520.

As illustrated in FIG. 19, the insulation module 10 includes a first light emitting diode 20AP, a second light emitting diode 20AQ, a first light receiving diode 30AP, a second light receiving diode 30AQ, a first control circuit 130A, and a second control circuit 130B. A drive current of 10 mA or less is supplied to each of the light emitting diodes 20AP and 20AQ. The first control circuit 130A and the second control circuit 130B are included in the control circuit 35PB (see FIG. 8). Although not illustrated, the first light emitting element 20P includes the first light emitting diode 20AP, and the second light emitting element 20Q includes the second light emitting diode 20AQ. The first light receiving element 30P includes the first light receiving diode 30AP and the first control circuit 130A, and the second light receiving element 30Q includes the second light receiving diode 30AQ and the second control circuit 130B.

The first light emitting diode 20AP includes the first electrode 21P (anode electrode) and the second electrode 22P (cathode electrode) of the first light emitting element 20P. The first electrode 21P of the first light emitting diode 20AP is electrically connected to the terminal 41A, and the second electrode 22P is electrically connected to the terminal 41B.

The first light receiving diode 30AP is a diode that receives light from the first light emitting diode 20AP. The first light receiving diode 30AP is electrically connected to the first control circuit 130A, and is insulated from the first light emitting diode 20AP. In other words, the first light emitting diode 20AP is insulated from the first control circuit 130A. The first light receiving diode 30AP includes the first electrode 31P and the second electrode 32P. In one example, the first electrode 31P is an anode electrode, and the second electrode 32P is a cathode electrode. Both the first electrode 31P and the second electrode 32P are electrically connected to the first control circuit 130A.

The first control circuit 130A includes a first Schmitt trigger 131A and a first output unit 132A. The first control circuit 130A generates a drive voltage signal based on a change in the voltage of the first light receiving diode 30AP caused when the first light receiving diode 30AP receives light from the first light emitting diode 20AP.

The first Schmitt trigger 131A is electrically connected to both the first electrode 31P and the second electrode 32P of the first light receiving diode 30AP. The first Schmitt trigger 131A is electrically connected to the terminals 51A and 51D. That is, power is supplied from the control power supply 503 to the first Schmitt trigger 131A. The first Schmitt trigger 131A transmits the voltage of the first light receiving diode 30AP to the first output unit 132A. A predetermined hysteresis is given to a threshold voltage of the first Schmitt trigger 131A. This configuration enhances the resistance to noise.

The first output unit 132A includes a first switching element 132Aa and a second switching element 132Ab connected in series to each other. In the example illustrated in FIG. 19, a p-type MOSFET is used as the first switching element 132Aa, and an n-type MOSFET is used as the second switching element 132Ab. As described above, the first output unit 132A is configured as a complementary MOS. The switching elements 132Aa and 132Ab of the first output unit 132A perform on/off operation at an input and output voltage in a range of 3V to 7V.

The source of the first switching element 132Aa is electrically connected to the terminal 51A. The source of the second switching element 132Ab is electrically connected to the terminal 51D. A node N between the drain of the first switching element 132Aa and the drain of the second switching element 132Ab is electrically connected to the terminal 51B.

Both the gate of the first switching element 132Aa and the gate of the second switching element 132Ab are electrically connected to the first Schmitt trigger 131A. That is, the signal from the first Schmitt trigger 131A is applied to both the gate of the first switching element 132Aa and the gate of the second switching element 132Ab.

The first output unit 132A generates a drive voltage signal by complementarily turning on and off the first switching element 132Aa and the second switching element 132Ab based on the signal of the first Schmitt trigger 131A. The first output unit 132A applies a drive voltage signal to the gate of the first switching element 511.

In the first modification, a signal formed by multiple pulses is input from the first light receiving element 30P to the first control circuit 130A. The first control circuit 130A outputs a drive voltage signal as an output signal to the gate of the first switching element 511 based on a portion of the pulses excluding the first pulse. The signal formed by the pulses is a pulse having a predetermined pulse period. For example, an interval between a first signal formed by multiple pulses and a second signal formed by multiple pulses transmitted after the first signal is longer than a pulse period. The configuration in which the drive voltage signal is output based on a portion of the pulses excluding the first pulse can also be applied to the above embodiment.

The second light emitting diode 20AQ includes a first electrode 21Q (anode electrode) and a second electrode 22Q (cathode electrode) of the second light emitting element 20Q. The first electrode 21Q of the second light emitting diode 20AQ is electrically connected to the terminal 41D, and the second electrode 22Q is electrically connected to the terminal 41C.

The second light receiving diode 30AQ is a diode that receives light from the second light emitting diode 20AQ. The second light receiving diode 30AQ is electrically connected to the second control circuit 130B, and is insulated from the second light emitting diode 20AQ. In other words, the second light emitting diode 20AQ is insulated from the second control circuit 130B. The second light receiving diode 30AQ includes the first electrode 31Q and the second electrode 32Q. In one example, the first electrode 31Q is an anode electrode, and the second electrode 32Q is a cathode electrode. Both the first electrode 31Q and the second electrode 32Q are electrically connected to the second control circuit 130B.

The second control circuit 130B includes a second Schmitt trigger 131B and a second output unit 132B. The second control circuit 130B generates a drive voltage signal based on a change in the voltage of the second light receiving diode 30AQ caused when the second light receiving diode 30AQ receives light from the second light emitting diode 20AQ.

The second Schmitt trigger 131B is electrically connected to both the first electrode 31Q and the second electrode 32Q of the second light receiving diode 30AQ. The second Schmitt trigger 131B is electrically connected to the terminals 51A and 51D. That is, power is supplied from the control power supply 503 to the second Schmitt trigger 131B. The second Schmitt trigger 131B transmits the voltage of the second light receiving diode 30AQ to the second output unit 132B. A predetermined hysteresis is given to a threshold voltage of the second Schmitt trigger 131B. This configuration enhances the resistance to noise.

The second output unit 132B has a first switching element 132Ba and a second switching element 132Bb connected in series with each other. In the example illustrated in FIG. 19, a p-type MOSFET is used as the first switching element 132Ba, and an n-type MOSFET is used as the second switching element 132Bb. As described above, in the first modification, the second output unit 132B is formed as a complementary MOS. Since the electrical connection manner of the first switching element 132Ba and the second switching element 132Bb is similar to the electrical connection manner of the first switching element 132Aa and the second switching element 132Ab, the detailed description thereof will be omitted.

In the first modification, a signal formed by multiple pulses is input from the second light receiving element 30Q to the second control circuit 130B. The second control circuit 130B outputs a drive voltage signal as an output signal to the gate of the first switching element 521 based on a portion of the pulses excluding the first pulse.

The connection manner between each of the light emitting diodes 20AP and 20AQ and the terminals 41A to 41D can be changed. In one example, the first electrode 21P of the first light emitting diode 20AP may be electrically connected to the terminal 41B, and the second electrode 22P may be electrically connected to the terminal 41A. The first electrode 21Q of the second light emitting diode 20AQ may be electrically connected to the terminal 41C, and the second electrode 22Q may be electrically connected to the terminal 41D.

In addition, the insulation module 10 may be applied to a controller area network (CAN) bus and an interface of serial peripheral interface (SPI) communication instead of being applied as an insulation type gate driver.

The insulation module 10 of the second modification may include one photocoupler. Although not illustrated, the insulation module 10 includes a light emitting element and a light receiving element configured to receive light from the light emitting element. The light emitting element has the same configuration as the first light emitting element 20P of the above embodiment, and the light receiving element has the same configuration as the first light receiving element 30P of the above embodiment.

As illustrated in FIG. 20, the inverter circuit 500 includes the first switching element 501 and the second switching element 502 connected in series with each other. Each of the switching element 501 and 502 is, for example, a transistor. An example of the transistor may be a MOSFET and an IGBT. In the second modification, a MOSFET is used for each of the switching element 501 and 502.

In the illustrated example, the insulation module 10 applies a drive voltage signal to the gate of the first switching element 501. That is, the insulation module 10 is a gate driver that drives the first switching element 501.

A positive electrode of a control power supply 503 is electrically connected to the terminal 51A of the insulation module 10. The terminal 51D of the insulation module 10 is connected between the source of the first switching element 501 and the drain of the second switching element 502.

The electrical configuration of the insulation module 10 is similar to, for example, the configuration in which the second light emitting diode 20AQ, the second light receiving diode 30AQ, and the second control circuit 130B are omitted from the insulation module 10 of the first modification illustrated in FIG. 19.

The insulation module 10 includes a light emitting diode 20R, a light receiving diode 30R, and a control circuit 130. The light emitting diode 20R has the same configuration as the first light emitting diode 20AP in the insulation module 10 of the first modification illustrated in FIG. 19, and the light receiving diode 30R has the same configuration as the first light receiving diode 30AP in the insulation module 10 of the first modification illustrated in FIG. 19.

The first electrode 21R of the light emitting diode 20R is electrically connected to the terminal 41A, and the second electrode 22R is electrically connected to the terminal 41B.

The light receiving diode 30R is electrically connected to the control circuit 130, and is insulated from the light emitting diode 20R. In one example, the first electrode 31R of the light receiving diode 30R is an anode electrode, and the second electrode 32R is a cathode electrode. Both the first electrode 31R and the second electrode 32R are electrically connected to the control circuit 130.

The control circuit 130 includes a Schmitt trigger 131 and an output unit 132 similarly to the first control circuit 130A in the insulation module 10 of the first modification illustrated in FIG. 19. The control circuit 130 generates a drive voltage signal based on a change in voltage of the light receiving diode 30R caused when the light receiving diode 30R receives light from the light emitting diode 20R.

The Schmitt trigger 131 is electrically connected to both the first electrode 31R and the second electrode 32R of the light receiving diode 30R. The Schmitt trigger 131 is electrically connected to the terminals 51A and 51D. That is, electric power is supplied to the Schmitt trigger 131 from the control power supply 503. The Schmitt trigger 131 transmits the voltage of the light receiving diode 30R to the output unit 132. A predetermined hysteresis is given to the threshold voltage of the Schmitt trigger 131. This configuration enhances the resistance to noise.

The output unit 132 includes a first switching element 132a and a second switching element 132b connected in series to each other. In the illustrated example, a p-type MOSFET is used as the first switching element 132a, and an n-type MOSFET is used as the second switching element 132b. The connection configuration of the switching elements 132a and 132b is similar to that of the insulation module 10 of the first modification illustrated in FIG. 19.

Both the gate of the first switching element 132a and the gate of the second switching element 132b are electrically connected to the Schmitt trigger 131. That is, a signal from the Schmitt trigger 131 is applied to both the gate of the first switching element 132a and the gate of the second switching element 132b.

The output unit 132 generates a drive voltage signal by complementarily turning on and off the first switching element 132a and the second switching element 132b based on the signal of the Schmitt trigger 131. The output unit 132 applies a drive voltage signal to the gate of the first switching element 501.

The insulation module 10 of the second modification illustrated in FIG. 20 may include a driver and a current source as in the above embodiment. The current source is provided between the terminal 41A and the first electrode 21R of the light emitting diode 20R. The driver is provided to connect the terminal 41C and the current source to each other, for example. As a result, the current supplied to the light emitting diode 20R is controlled according to the signal input to the terminal 41C.

As in the above embodiment, the insulation module 10 of the first modification illustrated in FIG. 19 may include the second driver 234B and the second current source 233B, which drive the first light emitting diode 20AP, and the first driver 234A and the first current source 233A, which drive the second light emitting diode 20AQ.

The term “on” as used in the present disclosure includes the meaning of “on” and “above” unless the context clearly dictates otherwise. Thus, the expression “A is formed on B” is intended that “A may be placed directly on B in contact with B” in the above embodiments, and is also intended that “A may be placed above B without contacting B”, as a modification. That is, the term “on” does not exclude structures in which other members are formed between A and B.

The description “at least one of A and B” in the present specification should be understood as meaning “only A, only B, or both A and B”.

### CLAUSES

Technical ideas obtainable from the present disclosure will be described below. For purposes of illustration and not of limitation, components described in the Clauses are labeled with the corresponding components in the embodiments. The reference numerals are given as examples to assist understanding, and the components described in each Clause should not be limited to the components indicated by the reference numerals.

Clause A1

An insulation module (10), including:
a light emitting element (20Q) and a light receiving element (30Q) forming a photocoupler;
an insulation member (70Q) having translucency and provided between the light receiving element (30Q) and the light emitting element (20Q);
a sealing plastic (80) that seals at least the light emitting element (20Q) and the light receiving element (30Q); and
a plurality of terminals (41A to 41D/51A to 51D) provided side by side on a plastic side surface (81/82) of the sealing plastic (80), in which
the insulation member (70Q) is stacked on a light receiving surface (33Q) of the light receiving element (30Q),
the light emitting element (20Q) is stacked on the insulation member (70Q), and
a first uneven portion (87/88) is provided in a portion between a first terminal and a second terminal among the terminals (41A to 41D/51A to 51D) on the plastic side surface (81/82).

Clause A2

The insulation module according to Clause A1, including a lead frame (40D) including a die pad (42DB) that supports the light receiving element (30P), in which
the lead frame (40D) includes a suspension lead (46D) extending from the die pad (42DB),
the suspension lead (46D) is exposed from the plastic side surface (81), and
on the plastic side surface (81), the first uneven portion (87) is provided at a portion between the suspension lead (46D) as the first terminal and a terminal (41A, 41B) adjacent to the suspension lead (46D) as the second terminal.

Clause A3

The insulation module according to Clause A1 or A2, including a bonding material for light emission (90Q) that bonds a side surface of the light emitting element (20Q) and the insulation member (70Q).

Clause A4

The insulation module according to Clause A3, in which
the light emitting element (20Q) includes a light emitting surface (20Qr) facing the light receiving surface (33Q), and
the light emitting surface (20Qr) is in contact with the insulation member (70Q).

Clause A5

The insulation module according to Clause A3 or A4, in which the bonding material for light emission (90Q) is formed of a plastic material that absorbs light.

Clause A6

The insulation module according to any one of Clauses A1 to A5, in which
the light emitting element (20Q) includes a back surface (20Qs) facing a side opposite to the light emitting surface (20Qr), and
a plurality of pads (21Q, 22Q) are provided on the back surface (20Qs).

Clause A7

The insulation module according to Clause A6, in which
the light emitting element (20P) includes a light emitting layer (25P) and a reflection layer (27P), and
the reflection layer (27P) is provided closer to the back surface (20Pr) than the light emitting layer (25P).

Clause A8

The insulation module according to any one of Clauses A1 to A7, in which a transparent plastic (60Q) that bonds the light receiving element (30Q) and the insulation member (70Q) is provided between the light receiving surface (33Q) of the light receiving element (30Q) and the insulation member (70Q).

Clause A9

The insulation module according to Clause A8, in which a thickness (T2) of the transparent plastic (60Q) is less than a thickness (T1) of the insulation member (70Q).

Clause A10

The insulation module according to Clause A8, in which a thickness (T2) of the transparent plastic (60Q) is greater than or equal to a thickness (T1) of the insulation member (70Q).

Clause A11

The insulation module according to any one of Clauses A8 to A10, in which a light transmittance of the insulation member (70Q) is lower than a light transmittance of the transparent plastic (60Q).

Clause A12

The insulation module according to any one of Clauses A8 to A10, in which a light transmittance of the insulation member (70Q) is greater than or equal to a light transmittance of the transparent plastic (60Q).

Clause A13

The insulation module according to any one of Clauses A1 to A12, in which
the light receiving element (30P) includes:
   a photoelectric conversion element (35PA); and
   a control circuit (35PB) which receives a signal from the photoelectric conversion element (35PA),
the photoelectric conversion element (35PA) and the control circuit (35PB) are provided side by side in a direction orthogonal to a thickness direction of the light receiving element (20P), and
the light emitting element (20P) is disposed on the light receiving element (30P) and is shifted toward the photoelectric conversion element (35P).

Clause A14

The insulation module according to any one of Clauses A1 to A13, in which the insulation member (70Q) includes a portion protruding from the light receiving element (30Q) when viewed in a stacking direction of the light emitting element (20Q) and the light receiving element (30Q).

Clause A15

The insulation module according to any one of Clauses A1 to A14, in which
the insulation member (70Q) includes:
   a first surface (70Qs) facing the light emitting element (20Q); and
   a second surface (70Qr) facing the light receiving element (30Q),
the first surface (70Qs) is formed to have a flat shape, and
a rough surface (75Q) that scatters light from the light emitting element (20Q) is formed on the second surface (70Qr).

Clause A16

The insulation module according to any one of Clauses A1 to A14, in which
the insulation member (70Q) includes:
   a first surface (70Qs) facing the light emitting element (20Q); and
   a second surface (70Qr) facing the light receiving element (30Q),
the first surface (70Qs) is formed to have a flat shape, and
a second uneven portion (74Q) is provided on the second surface (70Qr).

Clause A17

The insulation module according to any one of Clauses A1 to A16, including: a die pad (52DB) on which the light receiving element (30Q) is mounted; and
a bonding material for light reception (100Q) that bonds the die pad (52DB) and the light receiving element (30Q), in which
the light receiving element (30Q) includes a back surface (30Qr) facing a side opposite to the light receiving surface (33Q),
the bonding material for light reception (100Q) includes a first bonding region (101Q) interposed between the back surface (30Qr) and the die pad (52DB) and a second bonding region (102Q) protruding from the light receiving element (30Q) when viewed from the light receiving surface (33Q), and
a portion of the second bonding region (102Q) that is in contact with a side surface of the light receiving element (30Q) is formed to be closer to the light receiving surface (33Q) than a center of the light receiving element (30Q) in a thickness direction.

Clause A18

The insulation module according to any one of Clauses A1 to A17, in which the light emitting element (20P) includes a sapphire substrate.

Clause A19

The insulation module according to any one of Clauses A1 to A18, comprising a die pad (52DB) on which the light receiving element (30Q) is mounted, in which
the sealing plastic (80) includes a plastic main surface (80s) facing a same side as the light receiving surface (33Q) and a plastic back surface (80r) facing a same side as the light emitting surface (20Qr), and
the die pad (52DB) is disposed closer to the plastic back surface (80r) than a portion where the terminals (41A to 41D/51A to 51D) are exposed on the plastic side surface (81/82) in a stacking direction of the light emitting element (20Q) and the light receiving element (30Q).

Clause A20

The insulation module according to any one of Clauses A1 to A19, in which
the light emitting element includes a first light emitting element (20P) and a second light emitting element (20Q),
the light receiving element includes a first light receiving element (30P) and a second light receiving element (30Q),
the first light emitting element (20P) is stacked on the first light receiving element (30P), and the second light emitting element (20Q) is stacked on the second light receiving element (30Q), and
the insulation module (10) includes:
   a first die pad (42DB) on which the first light receiving element (30P) is mounted; and
   a second die pad (52DB) on which the second light receiving element (30Q) is mounted.

Clause A21

The insulation module according to any one of Clauses A1 to A20, in which the insulation member (70Q) includes inorganic particles that absorb or reflect light from the light emitting element (20Q).

Clause A22

The insulation module according to any one of Clauses A1 to A21, in which the transparent plastic (60Q) includes inorganic particles (61) that absorb or reflect light from the light emitting element (20Q).

Clause A23

The insulation module according to any one of Clauses A1 to A22, in which a thickness of the light emitting element (20Q) is less than a thickness of the light receiving element (30Q).

Clause A24

The insulation module according to any one of Clauses A1 to A23, in which a thickness of the insulation member (70Q) is less than a thickness of the light emitting element (20Q).

Clause A25

The insulation module according to Clause A15, in which the transparent plastic (60Q) is included in the second uneven portion (74Q).

Clause A26

The insulation module according to any one of Clauses A1 to A25, including a lead frame (40D) including a die pad (42DB) that supports the light receiving element (30P), in which
the lead frame (40D) includes a suspension lead (46D) extending from the die pad (42DB),
the plastic side surface includes a terminal surface (81/82) on which the terminals (41A to 41D/51A to 51D) are provided, and a suspension lead surface (83) that is a surface different from the terminal surface (81/82) and from which the suspension lead (46D) is drawn out.

Clause B1

An insulation module (10), including:
a light emitting element (20P) and a light receiving element (30P) forming a photocoupler;
an insulation member (70P) having translucency and provided between the light receiving element (20P) and the light emitting element (30P);
a sealing plastic (80) that seals at least the light emitting element (20P) and the light receiving element (30P), in which
the insulation member (70P) is stacked on a light receiving surface (33P) of the light receiving element (30P), and
the light emitting element (20P) is stacked on the insulation member (70P) and includes a sapphire substrate (23P).

Clause B2

The insulation module according to Clause B1, in which
the sapphire substrate (23P) has translucency,
the sapphire substrate (23P) includes:
   a substrate main surface facing a same side as the light receiving surface (33P); and
   a substrate back surface facing a side opposite to the substrate main surface,
the insulation module includes:
   a light emitting layer (25P) formed on the substrate main surface;
   a reflection layer (27P) formed on the light emitting layer (25P); and
   a pad (21P, 22P) provided on the reflection layer (27P), and
the substrate back surface forms a light emitting surface (20Pr) of the light emitting element (20P).

Clause B3

The insulation module according to Clause B2, in which
the insulation member (70P) includes:
   a first surface (70Ps) facing the light emitting element (20P); and
   a second surface (70Pr) facing the light receiving element (30P), and
the substrate back surface of the sapphire substrate (23P) is in contact with the first surface (70Ps) of the insulation member (70P).

Clause B4

The insulation module according to Clause B3, in which the sapphire substrate (23P) and the insulation member (90P) are bonded by an insulation bonding material (90P) that is in contact with a side surface of the sapphire substrate (23P) and the first surface (70Ps) of the insulation member (70P).

Clause B5

The insulation module according to Clause B4, in which the insulation bonding material (90P) has a light shielding property.

Clause C1

An insulation module, including:
a light emitting element (20P) and a light receiving element (30P) forming a photocoupler;
a die pad (42DB) on which the light receiving element (30P) is mounted; and
an insulation member (70P) having translucency and provided between the light receiving element (30P) and the light emitting element (20P);
a sealing plastic (80) which seals at least the light emitting element (20P) and the light receiving element (30P); and
a transparent plastic (60P) interposed between the light receiving element (30P) and the insulation member (70P) and bonding the light receiving element (30P) and the insulation member (70P), in which
the insulation member (70P) is stacked on a light receiving surface (33P) of the light receiving element (30P) via the transparent plastic (60P),
the light emitting element (20P) is stacked on the insulation member (70P), and
at least one of the transparent plastic (60P) and the insulation member (70P) includes inorganic particles (61) that absorb or reflect light from the light emitting element (20P).

Clause C2

The insulation module according to Clause C1, in which
the sealing plastic (80) includes:
   a plastic main surface (80s) that is a surface closer to the light emitting element (20P) than the light receiving element (30P) in a thickness direction (z-direction) of the sealing plastic (80); and
   a plastic back surface (80r) that is a surface closer to the light receiving element (30P) than the light emitting element (20P), and
the die pad (42DB) is formed to be inclined toward the plastic back surface (80r) with respect to a horizontal direction orthogonal to a thickness direction (z-direction) of the sealing plastic (80).

Clause C3

The insulation module according to Clause C2, in which
a terminal (41B) electrically connected to the die pad (42DB) is provided on a plastic side surface (81) of the sealing plastic (80) so as to protrude from the plastic side surface (81), and
the die pad (42DB) is disposed closer to the plastic back surface (80r) than a position where the terminal (41B) protrudes from the plastic side surface (81) in a thickness direction of the sealing plastic (80).

The above description is merely exemplary. Those skilled in the art will recognize that various further combinations and permutations are possible in addition to the components and methods (manufacturing process) that are listed for the purpose of describing the techniques of the present disclosure. The present disclosure is intended to cover all alternatives, variations, and modifications falling within the scope of this disclosure, including the claims and clauses.

### REFERENCE SIGNS LIST

10 . . . Insulation Module
20P . . . First Light Emitting Element
20Q . . . Second Light Emitting Element
20AP . . . First Light Emitting Diode
20AQ . . . Second Light Emitting Diode
20R . . . Light Emitting Diode
20Ps, 20Qs . . . Element Main Surface
20Pr, 20Qr . . . Element Back Surface
21P, 21Q, 21R . . . First Electrode
22P, 22Q, 22R . . . Second Electrode
23P . . . Substrate
24P . . . First Contact Layer
25P . . . Active Layer
26P . . . Second Contact Layer
27P . . . Reflection Layer
30P . . . First Light Receiving Element
30Q . . . Second Light Receiving Element
30AP . . . First Light Receiving Diode
30AQ . . . Second Light Receiving Diode
30R . . . Light Receiving Diode
30Ps, 30Qs . . . Element Main Surface
30Pr, 30Qr . . . Element Back Surface
31P, 31Q, 31R . . . First Electrode
32P, 32Q, 32R . . . Second Electrode
33P, 33Q . . . Light Receiving Surface
34P . . . Semiconductor Substrate
34Ps . . . Surface
34PA . . . First Semiconductor Region
34PB . . . Second Semiconductor Region
35PA . . . Photoelectric Conversion Element
35PB . . . Control Circuit
35PC . . . Insulation Wiring Layer
36P . . . Insulation Layer
36PA . . . First Insulation Portion
36PB . . . Second Insulation Portion
37PA to 37PE . . . Insulation Film
38PA to 38PE . . . Wiring Film
39PA to 39PD . . . Via
40, 40A to 40D . . . First Lead Frame
41, 41A to 41D . . . Terminal
42A to 42D . . . Inner Lead
42AA, 42BA, 42CA, 42DA . . . Lead Portion
42AB, 42BB, 42CB . . . Wire Connection Portion
42DB . . . Die Pad Portion
42Ds . . . Pad Main Surface
42Dr . . . Pad Back Surface
43D . . . First Portion
44D . . . Second Portion
45D . . . Wire Connection Portion
46D . . . Suspension lead
50, 50A to 50D . . . Second Lead Frame
51, 51A to 51D . . . First Terminal
52A to 52D . . . Inner Lead
52AA, 52BA, 52CA, 52DA . . . Lead Portion
52AB, 52BB, 52CB . . . Wire Connection Portion
52DB . . . Die Pad Portion
52Ds . . . Pad Main Surface
52Dr . . . Pad Back Surface
52DC . . . Wire Connection Portion
53D . . . Wire Connection Portion
54D . . . Through Hole
55D . . . Main Metal Layer
56D . . . Plating Layer
57D . . . Protrusion
60P . . . First Transparent plastic
60Q . . . Second Transparent plastic
61 . . . Inorganic Particles
70P . . . First Plate-Shaped Member
70Q . . . Second Plate-Shaped Member
70Ps, 70Qs . . . Main Surface
70Pr, 70Qr . . . Back Surface
71P, 71Q . . . First Extending Portion
72P, 72Q . . . Second Extending Portion
73P, 73Q . . . Intermediate Portion
74Q . . . Uneven Portion
74Qa . . . Recessed Section
75Q . . . Rough Surface
80 . . . Sealing plastic
80s . . . Plastic main surface
80r . . . Plastic back surface
81 . . . First Plastic side surface
82 . . . Second Plastic side surface
83 . . . Third Plastic side surface
84 . . . Fourth Plastic side surface
85 . . . First Side Surface
86 . . . Second Side Surface
87,88 . . . Uneven Portion
87a, 88a . . . Recessed Section
89 . . . Separation Wall Portion
90P, 90Q . . . Conductive Bonding Material
100P, 100Q . . . Conductive Bonding Material
101P, 101Q . . . First Bonding Region
102P, 102Q . . . Second Bonding Region
130A, 230A . . . First Control Circuit
131A, 231A . . . First Schmitt Trigger
132A, 232A . . . First Output Unit
132Aa, 232Aa . . . First Switching Element
132Ab, 232Ab . . . Second Switching Element
130B, 230B . . . Second Control Circuit
131B, 231B . . . Second Schmitt Trigger
132B, 232B . . . Second Output Unit
132Ba, 232Ba . . . First Switching Element
132Bb, 232Bb . . . Second Switching Element
130 . . . Control Circuit
131 . . . Schmitt Trigger
132 . . . Output Unit
132a . . . First Switching Element
132b . . . Second Switching Element
200 . . . Resin Layer
200s . . . Surface
233A . . . First Current Source
234A . . . First Driver
233B . . . Second Current Source
234B . . . Second Driver
500 . . . Inverter Circuit
510 . . . First Inverter Circuit
520 . . . Second Inverter Circuit
501, 511, 521 . . . First Switching Element
502, 512, 522 . . . Second Switching Element
503, 504 . . . Control Power Supply
505 . . . Detection Circuit
WA1 to WA4, WB1 to WB4, WC1 to WC4 . . . Wire

1. An insulation module, comprising:
a light emitting element and a light receiving element forming a photocoupler;
an insulation member having translucency and provided between the light receiving element and the light emitting element;
a sealing plastic that seals at least the light emitting element and the light receiving element; and
a plurality of terminals provided side by side on a plastic side surface of the sealing plastic, wherein
the insulation member is stacked on a light receiving surface of the light receiving element,
the light emitting element is stacked on the insulation member, and
a first uneven portion is provided in a portion between a first terminal and a second terminal among the plurality of terminals on the plastic side surface.

2. The insulation module according to claim 1, further comprising a lead frame including a die pad that supports the light receiving element, wherein
the lead frame includes a suspension lead extending from the die pad,
the suspension lead is exposed from the plastic side surface, and
on the plastic side surface, the first uneven portion is provided at a portion between the suspension lead as the first terminal and a terminal adjacent to the suspension lead as the second terminal.

3. The insulation module according to claim 1, further comprising a bonding material for light emission that bonds a side surface of the light emitting element and the insulation member.

4. The insulation module according to claim 3, wherein
the light emitting element includes a light emitting surface facing the light receiving surface, and
the light emitting surface is in contact with the insulation member.

5. The insulation module according to claim 3, wherein the bonding material for light emission is formed of a plastic material that absorbs light.

6. The insulation module according to claim 1, wherein
the light emitting element includes a light emitting surface facing the light receiving surface,
the light emitting element includes a back surface facing a side opposite to the light emitting surface, and
a plurality of pads are provided on the back surface.

7. The insulation module according to claim 6, wherein
the light emitting element includes a light emitting layer and a reflection layer, and
the reflection layer is provided closer to the back surface than the light emitting layer.

8. The insulation module according to claim 1, wherein a transparent plastic that bonds the light receiving element and the insulation member to each other is provided between the light receiving surface of the light receiving element and the insulation member.

9. The insulation module according to claim 8, wherein a thickness of the transparent plastic is less than a thickness of the insulation member.

10. The insulation module according to claim 8, wherein a thickness of the transparent plastic is greater than or equal to a thickness of the insulation member.

11. The insulation module according to claim 8, wherein a light transmittance of the insulation member is lower than a light transmittance of the transparent plastic.

12. The insulation module according to claim 8,
wherein a light transmittance of the insulation member is greater than or equal to a light transmittance of the transparent plastic.

13. The insulation module according to claim 1, wherein the light receiving element includes:
a photoelectric conversion element; and
a control circuit that receives a signal from the photoelectric conversion element,
the photoelectric conversion element and the control circuit are provided side by side in a direction orthogonal to a thickness direction of the light receiving element, and
the light emitting element is disposed on the light receiving element and is shifted toward the photoelectric conversion element.

14. The insulation module according to claim 1, wherein the insulation member includes a portion protruding from the light receiving element when viewed in a stacking direction of the light emitting element and the light receiving element.

15. The insulation module according to claim 1, wherein the insulation member includes:
a first surface facing the light emitting element; and
a second surface facing the light receiving element,
the first surface is formed to have a flat shape, and
a rough surface that scatters light from the light emitting element is formed on the second surface.

16. The insulation module according to claim 1, wherein the insulation member includes:
a first surface facing the light emitting element; and
a second surface facing the light receiving element,
the first surface is formed to have a flat shape, and
a second uneven portion is provided on the second surface.

17. The insulation module according to claim 1, further comprising:
a die pad on which the light receiving element is mounted; and
a bonding material for light reception that bonds the die pad and the light receiving element to each other, wherein
the light receiving element includes a back surface facing a side opposite to the light receiving surface,
the bonding material for light reception includes a first bonding region interposed between the back surface and the die pad and a second bonding region protruding from the light receiving element when viewed from the light receiving surface, and
a portion of the second bonding region that is in contact with a side surface of the light receiving element is formed to be closer to the light receiving surface than a center of the light receiving element in a thickness direction.

18. The insulation module according to claim 1, wherein the light emitting element includes a sapphire substrate.

19. The insulation module according to claim 1, further comprising a die pad on which the light receiving element is mounted, wherein
the light emitting element includes a light emitting surface facing the light receiving surface,
the sealing plastic includes a plastic main surface facing a same side as the light receiving surface and a plastic back surface facing a same side as the light emitting surface, and
the die pad is disposed closer to the plastic back surface than a portion where the terminals are exposed on the plastic side surface in a stacking direction of the light emitting element and the light receiving element.

20. The insulation module according to claim 1, wherein
the light emitting element includes a first light emitting element and a second light emitting element,
the light receiving element includes a first light receiving element and a second light receiving element,
the first light emitting element is stacked on the first light receiving element, and the second light emitting element is stacked on the second light receiving element, and
the insulation module further includes:
a first die pad on which the first light receiving element is mounted; and
a second die pad on which the second light receiving element is mounted.
